(19) United States
(12) Patent Application Publication
(10) Pub. No.: US 2026/0255482 A1
(43) Pub. Date: Aug. 27, 2026

(54) WIRING SUBSTRATE, ELECTRONIC DEVICE, AND ELECTRONIC MODULE

(71) Applicant: KYOCERA CORPORATION, Kyoto-shi, Kyoto (JP)

(72) Inventor: Shinichiro SAWA, Kirishima-shi (JP)

(73) Assignee: KYOCERA CORPORATION, Kyoto-shi, Kyoto (JP)

(21) Appl. No.: 18/714,232

(22) PCT Filed: Nov. 29, 2022
(86) PCT No.: PCT/JP2022/043914

§ 371 Date: May 29, 2024

(30) Foreign Application Priority Data
Nov. 30, 2021 (JP) 2021-193727

(51) Int. Cl. H05K 1/11; H05K 1/02

(52) U.S. Cl. CPC H05K 1/115; H05K 1/0219

(57) ABSTRACT

A wiring substrate includes an insulating substrate, a first line and a second line positioned adjacent to each other on the insulating substrate, and a ground film conductor and a ground via conductor positioned on the insulating substrate and surrounding the first line and the second line. In a plan perspective view, a first line conductor and a third line conductor include portions having a distance increasing toward a first via conductor and a third via conductor, and a second line conductor and a fourth line conductor include portions having a distance decreasing toward a second via conductor and a fourth via conductor.

### TECHNICAL FIELD

The present disclosure relates to a wiring substrate, an electronic device, and an electronic module.

### BACKGROUND

Japanese Unexamined Patent Application Publication No. 2009-212400 discloses a wiring substrate including a signal line extending from a substrate surface to the other substrate surface.

### SUMMARY

According to the present disclosure, a wiring substrate includes an insulating substrate, a first line and a second line, and a ground film conductor and a ground via conductor. The first line and the second line are positioned adjacent to each other on the insulating substrate. The ground film conductor and the ground via conductor are positioned on the insulating substrate and surround the first line and the second line. The first line includes a first line conductor, a first via conductor, a second line conductor, and a second via conductor. The first via conductor is connected to the first line conductor. The second line conductor is connected to the first via conductor and extends opposite from the first line conductor with the first via conductor being interposed therebetween in a plan perspective view. The second via conductor is connected to the second line conductor and extends to a layer different from a layer including the first via conductor. The second line includes a third line conductor, a third via conductor, a fourth line conductor, and a fourth via conductor. The third via conductor is connected to the third line conductor. The fourth line conductor is connected to the third via conductor and extends opposite from the third line conductor with the third via conductor being interposed therebetween in a plan perspective view. The fourth via conductor is connected to the fourth line conductor and extends to a layer different from a layer including the third via conductor. In a plan perspective view, the first line conductor and the third line conductor include portions having a distance increasing toward the first via conductor and the third via conductor, and the second line conductor and the fourth line conductor include portions having a distance decreasing toward the second via conductor and the fourth via conductor.

According to the present disclosure, an electronic device includes the wiring substrate and an electron element mounted on the wiring substrate.

According to the present disclosure, an electronic module includes the electronic device, and a module substrate equipped with the electronic device.

### BRIEF DESCRIPTION OF THE DRAWINGS

FIG. 1A is a plan perspective view of a wiring substrate according to embodiment 1 of the present disclosure.

FIG. 1B is a longitudinal sectional view of the wiring substrate cut along a signal line in embodiment 1 of the present disclosure.

FIG. 2 is a plan perspective view from above of a principal part of the wiring substrate according to embodiment 1.

FIG. 3A is a transverse sectional view of a third layer in the principal part in FIG. 2.

FIG. 3B is a transverse sectional view of a fourth layer in the principal part in FIG. 2.

FIG. 3C is a transverse sectional view of fifth to tenth layers in the principal part in FIG. 2.

FIG. 4A is a transverse sectional view of an eleventh layer in the principal part in FIG. 2.

FIG. 4B is a transverse sectional view of a twelfth layer in the principal part in FIG. 2.

FIG. 4C is a transverse sectional view of a thirteenth layer in the principal part in FIG. 2.

FIG. 5A is a transverse sectional view of a fourteenth layer in the principal part in FIG. 2.

FIG. 5B is a view of a rear surface in the principal part in FIG. 2.

FIG. 6A is a longitudinal sectional view taken along line A-A in FIG. 3B.

FIG. 6B is a longitudinal sectional view taken along line B-B in FIG. 3B.

FIG. 6C is a longitudinal sectional view taken along line C-C in FIG. 5A.

FIG. 6D is a longitudinal sectional view taken along line D-D in FIG. 5A.

FIG. 7A is a graph indicating return losses of the wiring substrate according to embodiment 1 and a wiring substrate according to a comparative example.

FIG. 7B is a graph indicating insertion losses of the wiring substrate according to embodiment 1 and the wiring substrate according to the comparative example.

FIG. 8A is a plan perspective view of a principal part of a wiring substrate according to embodiment 2 of the present disclosure.

FIG. 8B is a longitudinal sectional view of the principal part of the wiring substrate cut along a signal line in embodiment 2 of the present disclosure.

FIG. 9A is a transverse sectional view of a third layer in the principal part in FIG. 8A.

FIG. 9B is a transverse sectional view of a fourth layer in the principal part in FIG. 8A.

FIG. 9C is a transverse sectional view of fifth to ninth layers in the principal part in FIG. 8A.

FIG. 10A is a transverse sectional view of a tenth layer in the principal part in FIG. 8A.

FIG. 10B is a transverse sectional view of an eleventh layer in the principal part in FIG. 8A.

FIG. 10C is a transverse sectional view of a twelfth layer in the principal part in FIG. 8A.

FIG. 11A is a transverse sectional view of a thirteenth layer in the principal part in FIG. 8A.

FIG. 11B is a transverse sectional view of a fourteenth layer in the principal part in FIG. 8A.

FIG. 11C is a view of a rear surface in the principal part in FIG. 8A.

FIG. 12A is a longitudinal sectional view taken along line A-A in FIG. 9B.

FIG. 12B is a longitudinal sectional view taken along line B-B in FIG. 9B.

FIG. 12C is a longitudinal sectional view taken along line C-C in FIG. 10C.

FIG. 13A is a longitudinal sectional view taken along line D-D in FIG. 10C.

FIG. 13B is a longitudinal sectional view taken along line E-E in FIG. 11B.

FIG. 13C is a longitudinal sectional view taken along line F-F in FIG. 11B.

FIG. 14 is a view of an electronic device and an electronic module according to an embodiment of the present disclosure.

FIG. 15A is a plan perspective view of a wiring substrate according to embodiment 3 of the present disclosure.

FIG. 15B is a longitudinal sectional view of the wiring substrate cut along a signal line in embodiment 3.

FIG. 16 is a plan perspective view from above of a principal part of the wiring substrate according to embodiment 3.

FIG. 17A is a plan perspective view of a wiring substrate according to embodiment 4 of the present disclosure.

FIG. 17B is a longitudinal sectional view of the wiring substrate cut along a signal line in embodiment 4.

FIG. 18 is a plan perspective view from above of a principal part of the wiring substrate according to embodiment 4.

FIG. 19A is a transverse sectional view of a third layer in the principal part in FIG. 18.

FIG. 19B is a transverse sectional view of a fourth layer in the principal part in FIG. 18.

FIG. 19C is a transverse sectional view of fifth to tenth layers in the principal part in FIG. 18.

FIG. 19D is a transverse sectional view of an eleventh layer in the principal part in FIG. 18.

FIG. 19E is a transverse sectional view of a twelfth layer in the principal part in FIG. 18.

FIG. 19F is a transverse sectional view of a thirteenth layer in the principal part in FIG. 18.

FIG. 19G is a transverse sectional view of a fourteenth layer in the principal part in FIG. 18.

FIG. 19H is a view of a rear surface in the principal part in FIG. 18.

FIG. 20A is a plan perspective view of a wiring substrate according to embodiment 5 of the present disclosure.

FIG. 20B is a longitudinal sectional view of the wiring substrate cut along a signal line in embodiment 5.

### DETAILED DESCRIPTION

Embodiments of the present disclosure will be described in detail hereinafter with reference to the drawings.

### Embodiment 1

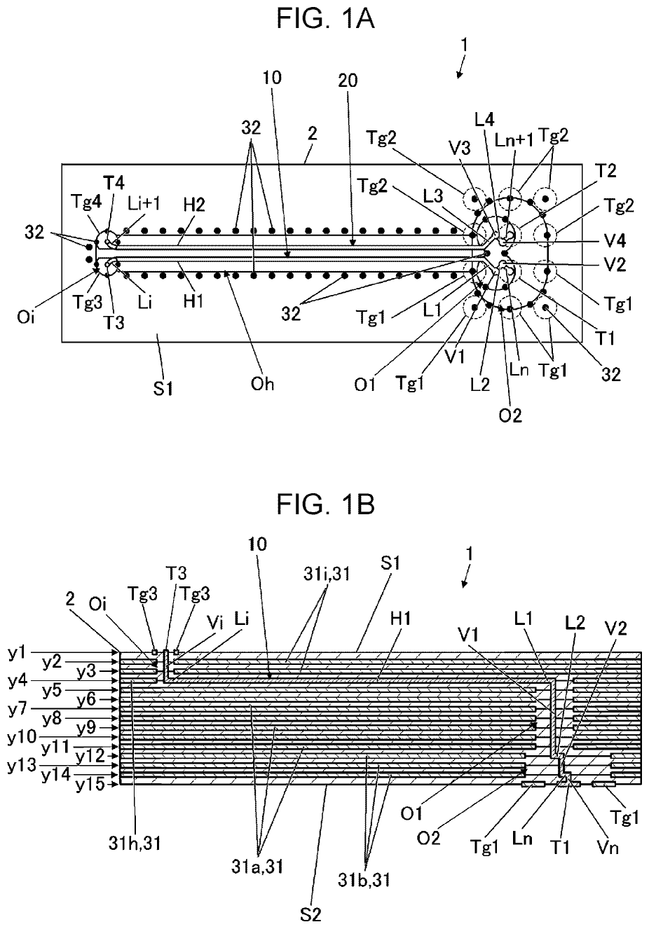

FIGS. 1A and 1B illustrate a wiring substrate according to embodiment 1 of the present disclosure. FIG. 1A is a plan perspective view of the wiring substrate, and FIG. 1B is a longitudinal sectional view of the wiring substrate cut along a signal line.

Embodiment 1 provides a wiring substrate 1 including an insulating substrate 2 including a first surface S1 and a second surface S2 positioned opposite to the first surface S1, and a first line 10 and a second line 20 positioned adjacent to each other on the insulating substrate 2. The insulating substrate 2 is a substrate made of a ceramic, a resin, or the like and having insulation characteristics, and may have a stacked structure. The first line 10 and the second line 20 correspond to a pair of differential lines for differential signal transmission and may be lines for broadband signal transmission. The broadband may be a band for 1 GHz to 60 GHz.

The wiring substrate 1 may further include a plurality of ground film conductors 31 and a plurality of ground via conductors 32, which are positioned on the insulating substrate 2 and surround the first line 10 and the second line 20. The plurality of ground film conductors 31 and the plurality of ground via conductors 32 may be configured to collectively surround the first line 10 and the second line 20.

The first line 10 may include a third electrode T3, an i-th via conductor Vi, an i-th line conductor Li, a first parallel line conductor H1, a first line conductor L1, a first via conductor V1, a second line conductor L2, a second via conductor V2, an n-th line conductor Ln, an n-th via conductor Vn, and a first electrode T1, which are provided in the mentioned order from the first surface S1 to the second surface S2 of the insulating substrate 2. The first electrode T1 is positioned on the second surface S2 of the insulating substrate 2. The third electrode T3 is positioned on the first surface S1 of the insulating substrate 2.

The second line 20 may include a fourth electrode T4, an (i+1)-th via conductor Vi+1, an (i+1)-th line conductor Li+1, a second parallel line conductor H2, a third line conductor L3, a third via conductor V3, a fourth line conductor L4, a fourth via conductor V4, an (n+1)-th line conductor Ln+1, an (n+1)-th via conductor Vn+1, and a second electrode T2, which are provided in the mentioned order from the first surface S1 to the second surface S2 of the insulating substrate 2. The second electrode T2 is positioned on the second surface S2 of the insulating substrate 2. The fourth electrode T4 is positioned on the first surface S1 of the insulating substrate 2.

In the following description, in a thickness direction of the wiring substrate 1, a side of the first surface S1 is referred to as an “upward side”, and a side of the second surface S2 is referred to as a “downward side”. Furthermore, in a direction in which the parallel line conductors (H1 and H2) extend, a side provided with the third electrode T3 and the fourth electrode T4 is referred to as a “leftward side”, and a side provided with the first electrode T1 and the second electrode T2 is referred to as a “rightward side”.

The wiring substrate 1 may include a plurality of layers (a first layer y1 to a fifteenth layer y15) each provided with any one of the electrodes (the first electrode T1 to the fourth electrode T4), the line conductors (the i-th line conductor Li to the (n+1)-th line conductor Ln+1), and the plurality of ground film conductors 31. The first layer y1 corresponds to a surface layer on the side of the first surface S1, and the fifteenth layer y15 corresponds to a surface layer on the side of the second surface S2. The plurality of layers is aligned vertically.

The first line 10 may include the third electrode T3, the i-th line conductor Li, the first parallel line conductor H1, the first line conductor L1, the second line conductor L2, the n-th line conductor Ln, and the first electrode T1, which are continuously disposed in the mentioned order from leftward to rightward in a plan perspective view (perspective view perpendicular to the first surface S1).

Among the plurality of line conductors (conductors extending along the first surface S1) included in the first line 10, the i-th line conductor Li, the first parallel line conductor H1, and the first line conductor L1 may be positioned in an identical layer. The first line conductor L1, the second line conductor L2, and the n-th line conductor Ln may be positioned in the mentioned order from upward to downward.

The plurality of line conductors (the i-th line conductor Li, the first parallel line conductor H1, the first line conductor L1, the second line conductor L2, and the n-th line conductor Ln) included in the first line 10 may have an identical line width.

The i-th via conductor Vi may be positioned from a layer including the third electrode T3 to a layer including the i-th line conductor Li. The first via conductor V1 may be positioned from a layer including the first line conductor L1 to a layer including the second line conductor L2. The second via conductor V2 may be positioned from a layer including the second line conductor L2 to a layer including the n-th line conductor Ln. The n-th via conductor Vn may be positioned from a layer including the n-th line conductor Ln to a layer including the first electrode T1 (a layer including the second surface S2).

The third electrode T3 may be positioned in the first layer y1. The i-th line conductor Li, the first parallel line conductor H1, and the first line conductor L1 may be positioned in the fourth layer y4. The second line conductor L2 may be positioned in the twelfth layer y12. The n-th line conductor Ln may be positioned in the fourteenth layer y14.

The third electrode T3 may be connected to an upper part of the i-th via conductor Vi. The i-th via conductor Vi has a lower part that may be connected to a left part of the i-th line conductor Li. The i-th line conductor Li has a right part that may be connected to a left part of the first parallel line conductor H1. The first parallel line conductor H1 has a right part that may be connected to a left part of the first line conductor L1. The first line conductor L1 has a right part that may be connected to an upper part of the first via conductor V1. The first via conductor V1 has a lower part that may be connected to a left part of the second line conductor L2. The second line conductor L2 has a right part that may be connected to an upper part of the second via conductor V2. The second via conductor V2 has a lower part that may be connected to a left part of the n-th line conductor Ln. The n-th line conductor Ln has a right part that may be connected to an upper part of the n-th via conductor Vn. The n-th via conductor Vn has a lower part that may be connected to the first electrode T1. The upper part and the lower part as connected positions may alternatively be called an upper end and a lower end, respectively. The left part and the right part as connected positions may alternatively be called a left end and a right end, respectively.

The second line 20 may include the fourth electrode T4, the (i+1)-th line conductor Li+1, the second parallel line conductor H2, the third line conductor L3, the fourth line conductor L4, the (n+1)-th line conductor Ln+1, and the second electrode T2, which are continuously disposed in the mentioned order from leftward to rightward in a plan perspective view (perspective view perpendicular to the first surface S1).

Among the plurality of line conductors (conductors extending along the first surface S1) included in the second line 20, the (i+1)-th line conductor Li+1, the second parallel line conductor H2, and the third line conductor L3 may be positioned in an identical layer. The third line conductor L3, the fourth line conductor L4, and the (n+1)-th line conductor Ln+1 may be positioned in the mentioned order from upward to downward.

The plurality of line conductors (the (i+1)-th line conductor Li+1, the second parallel line conductor H2, the third line conductor L3, the fourth line conductor L4, and the (n+1)-th line conductor Ln+1) included in the second line 20 may have an identical line width. The plurality of line conductors included in the second line 20 may be identical in line width to the plurality of line conductors included in the first line 10.

The (i+1)-th via conductor Vi+1 may be positioned from a layer including the fourth electrode T4 (a layer including the first surface S1) to the layer including the second parallel line conductor H2 and the third line conductor L3. The third via conductor V3 may be positioned from the layer including the third line conductor L3 to a layer including the fourth line conductor LA. The fourth via conductor V4 may be positioned from the layer including the fourth line conductor L4 to a layer including the (n+1)-th line conductor Ln+1. The (n+1)-th via conductor Vn+1 may be positioned from the layer including the (n+1)-th line conductor Ln+1 to a layer including the second electrode T2 (the layer including the second surface S2).

The fourth electrode T4 may be positioned in the first layer y1. The (i+1)-th line conductor Li+1, the second parallel line conductor H2, and the third line conductor L3 may be positioned in the fourth layer y4. The fourth line conductor LA may be positioned in the twelfth layer y12. The (n+1)-th line conductor Ln+1 may be positioned in the fourteenth layer y14.

The fourth electrode T4 may be connected to an upper part of the (i+1)-th via conductor Vi+1. The (i+1)-th via conductor Vi+1 has a lower part that may be connected to a left part of the (i+1)-th line conductor Li+1. The (i+1)-th line conductor Li+1 has a right part that may be connected to a left part of the second parallel line conductor H2. The second parallel line conductor H2 has a right part that may be connected to a left part of the third line conductor L3. The third line conductor L3 has a right part that may be connected to an upper part of the third via conductor V3. The third via conductor V3 has a lower part that may be connected to a left part of the fourth line conductor L4. The fourth line conductor LA has a right part that may be connected to an upper part of the fourth via conductor V4. The fourth via conductor V4 has a lower part that may be connected to a left part of the (n+1)-th line conductor Ln+1. The (n+1)-th line conductor Ln+1 has a right part that may be connected to an upper part of the (n+1)-th via conductor Vn+1. The (n+1)-th via conductor Vn+1 has a lower part that may be connected to the second electrode T2. The upper part and the lower part as connected positions may alternatively be called the upper end and the lower end, respectively. The left part and the right part as connected positions may alternatively be called the left end and the right end, respectively.

In the first line 10 and the second line 20, the i-th line conductor Li, the (i+1)-th line conductor Li+1, the first parallel line conductor H1, the second parallel line conductor H2, the first line conductor L1, and the third line conductor L3 may be positioned in an identical layer. The second line conductor L2 and the fourth line conductor L4 may be positioned in an identical layer. The n-th line conductor Ln and the (n+1)-th line conductor Ln+1 may be positioned in an identical layer.

The first parallel line conductor H1 and the second parallel line conductor H2 may be parallel with each other. The first parallel line conductor H1 and the second parallel line conductor H2 may be straight or partially bent.

In the first line 10 and the second line 20, the i-th via conductor Vi and the (i+1)-th via conductor Vi+1 may be positioned through identical layers. The first via conductor V1 and the third via conductor V3 may be positioned through identical layers. The second via conductor V2 and the fourth via conductor V4 may be positioned through identical layers. The n-th via conductor Vn and the (n+1)-th via conductor Vn+1 may be positioned through identical layers.

The third electrode T3 and the fourth electrode T4 may be aligned in an anteroposterior direction (a direction orthogonal to a lateral direction and along the first surface S1 or the second surface S2). The first electrode T1 and the second electrode T2 may be aligned in the anteroposterior direction. The first electrode T1 and the second electrode T2 may be larger in area than the third electrode T3 and the fourth electrode T4. A distance between a center of the first electrode T1 and a center of the second electrode T2 may be longer than a distance between a center of the third electrode T3 and a center of the fourth electrode T4.

The plurality of ground film conductors 31 may be positioned respectively in all the layers excluding the surface layer of the insulating substrate 2 (the second layer y2 to the fourteenth layer y14). The plurality of ground film conductors 31 may include one or a plurality of ground film conductors 31i including an opening Oi surrounding the i-th via conductor Vi and the (i+1)-th via conductor Vi+1, one or a plurality of ground film conductors 31h including a belt-shaped opening Oh surrounding the first parallel line conductor H1 and the second parallel line conductor H2, and a plurality of first ground film conductors 31a and a plurality of second ground film conductors 31b including a first opening O1 and a second opening O2, respectively, which will be described later. The opening Oh in the ground film conductor 31h in the fourth layer y4 may have a shape combining a belt-shaped portion along the first parallel line conductor H1 and the second parallel line conductor H2, a portion shaping the opening Oh, and a portion shaping the first opening O1.

The plurality of ground via conductors 32 may be positioned to surround at least the openings Oi and Oh, the first opening O1, and the second opening O2. Among the plurality of ground via conductors 32, two ground via conductors 32 adjacent to each other may be spaced apart from each other.

The wiring substrate 1 may further include a third ground electrode Tg3 surrounding the third electrode T3, and a fourth ground electrode Tg4 surrounding the fourth electrode T4. The third ground electrode Tg3 and the fourth ground electrode Tg4 may be positioned on the first surface S1 of the insulating substrate 2 and may be connected to the ground film conductor 31 through the ground via conductor 32.

The wiring substrate 1 may further include a plurality of first ground electrodes Tg1 and a plurality of second ground electrodes Tg2 which surround the first electrode T1 and the second electrode T2. The plurality of first ground electrodes Tg1 and the plurality of second ground electrodes Tg2 may be positioned on the second surface S2 and may be spaced apart from and surround the first electrode T1 and the second electrode T2.

The plurality of first ground electrodes Tg1 and the plurality of second ground electrodes Tg2 may be larger in individual area than the third ground electrode Tg3 and the fourth ground electrode Tg4. The first ground electrodes Tg1 and the second ground electrodes Tg2 surround a region that may be larger in area than a region surrounded by the third ground electrode Tg3 and the fourth ground electrode Tg4. This configuration enables a precise wiring connection on the first surface S1 and a broad wiring connection on the second surface S2. In this configuration, the third electrode T3 and the fourth electrode T4 on the first surface S1 are connected to an electron element, and the first electrode T1 and the second electrode T2 on the second surface S2 are connected to an electrode on a module substrate. This configuration facilitates the wiring connections.

The wiring substrate 1 having the above configuration achieves broadband differential signal transmission between the first surface S1 and the second surface S2 of the insulating substrate 2.

### Details of First Line 10 and Second Line 20

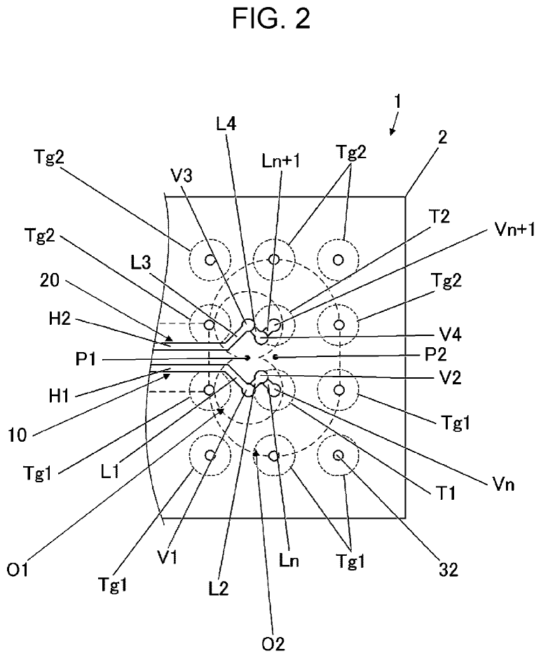

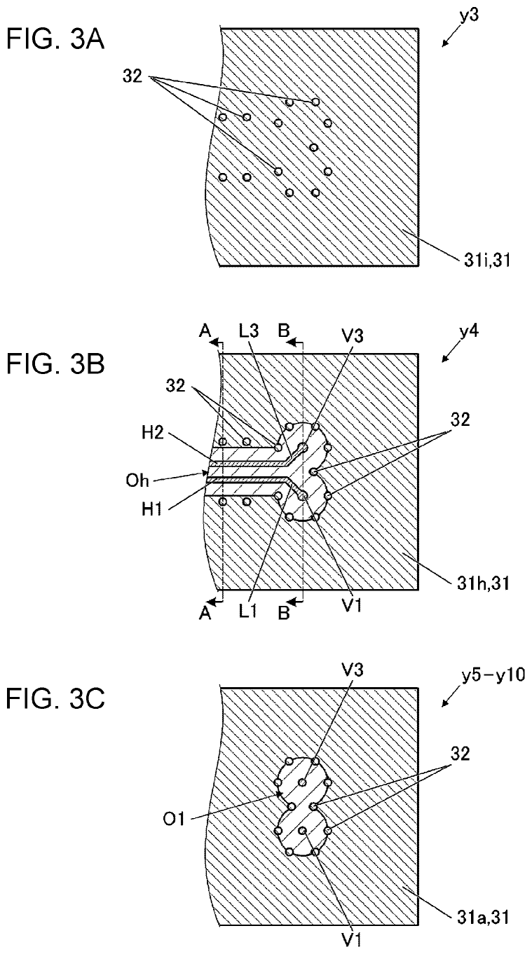

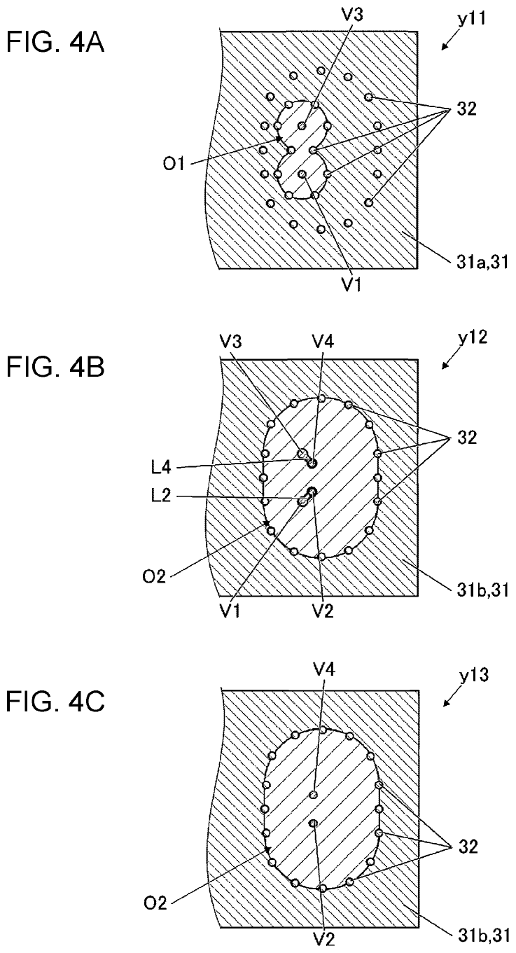

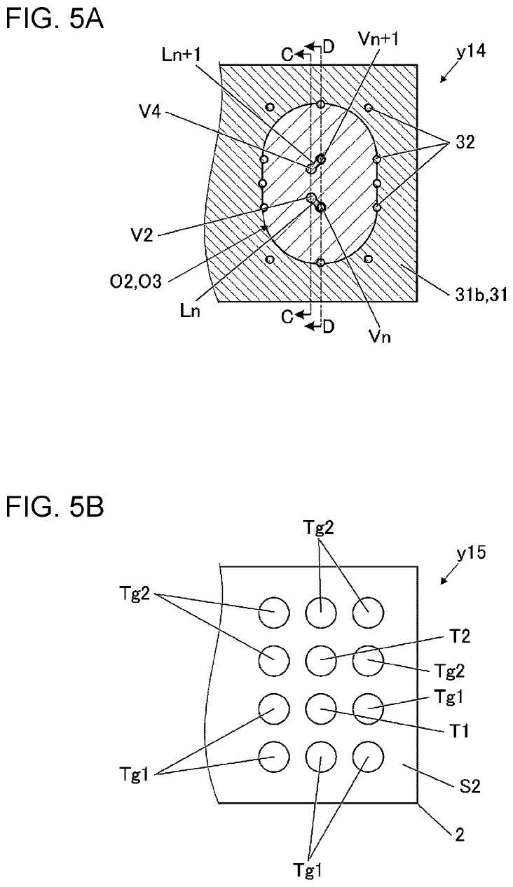

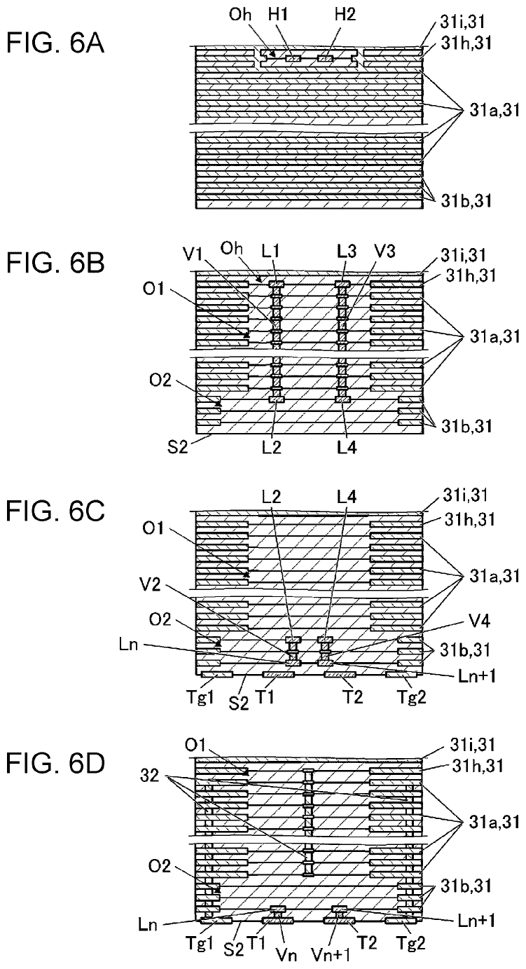

FIG. 2 is a plan perspective view from above of a principal part of the wiring substrate according to embodiment 1. FIGS. 3A to 3C are transverse sectional views respectively illustrating the third layer, the fourth layer, and the fifth to tenth layers in the principal part in FIG. 2. FIGS. 4A to 4C are transverse sectional views respectively illustrating the eleventh layer, the twelfth layer, and the thirteenth layer in the principal part in FIG. 2. FIG. 5A is a transverse sectional view of the fourteenth layer in the principal part in FIG. 2. FIG. 5B is a view of a rear surface in the principal part in FIG. 2. FIG. 5B perspectively illustrates the rear surface from above. FIG. 6A is a longitudinal sectional view taken along line A-A in FIG. 3B, FIG. 6B is a longitudinal sectional view taken along line B-B in FIG. 3B, FIG. 6C is a longitudinal sectional view taken along line C-C in FIG. 5A, and FIG. 6D is a longitudinal sectional view taken along line D-D in FIG. 5A.

Also in the following description, in the thickness direction of the wiring substrate 1, the side of the first surface S1 (FIG. 1B) is referred to as the “upward side”, and the side of the second surface S2 is referred to as the “downward side”. Furthermore, in the direction in which the parallel line conductors (H1 and H2) extend, the side provided with the third electrode T3 and the fourth electrode T4 is referred to as the “leftward side”, and the side provided with the first electrode T1 and the second electrode T2 is referred to as the “rightward side”.

The first line conductor L1 and the third line conductor L3 may have a distance gradually increasing toward the right (FIG. 3B). The second line conductor L2 and the fourth line conductor L4 may have a distance gradually decreasing toward the right (FIG. 4B). In this configuration, the distance between the second via conductor V2 and the fourth via conductor V4 is smaller than the distance between the first via conductor V1 and the third via conductor V3 (FIGS. 6B and 6C), and the first line 10 and the second line 20 can have larger inductance components near the first electrode T1 and the second electrode T2. The large inductance components act to cancel capacitance components of the first electrode T1 and the second electrode T2, so as to achieve excellent signal transmission characteristics from a low frequency to a high frequency.

The first line conductor L1 and the third line conductor L3 may include portions having the distance increasing toward the first via conductor V1 and the third via conductor V3 in a planar view. That is, in a planar view, the first line conductor L1 may have an arc or circular arc shape projecting toward the third line conductor L3, an arc or circular arc shape depressed from the third line conductor L3, a zigzag shape bent at a right or certain angle at one or a plurality of points, a stepped shape, or a shape obtained by combining any of these shapes. Similarly, in a planar view, the third line conductor L3 may have an arc or circular arc shape projecting toward the first line conductor L1, an arc or circular arc shape depressed from the first line conductor L1, a zigzag shape bent at a right or certain angle at one or a plurality of points, a stepped shape, or a shape obtained by combining any of these shapes.

Furthermore, the second line conductor L2 and the fourth line conductor L4 may include portions having the distance decreasing toward the second via conductor V2 and the fourth via conductor V4 in a planar view. That is, in a planar view, the second line conductor L2 may have an arc or circular arc shape projecting toward the fourth line conductor L4, an arc or circular arc shape depressed from the fourth line conductor L4, a zigzag shape bent at a right or certain angle at one or a plurality of points, a stepped shape, or a shape obtained by combining any of these shapes. Similarly, in a planar view, the fourth line conductor L4 may have an arc or circular arc shape projecting toward the second line conductor L2, an arc or circular arc shape depressed from the second line conductor L2, a zigzag shape bent at a right or certain angle at one or a plurality of points, a stepped shape, or a shape obtained by combining any of these shapes.

Also in the above configuration, the distance between the second via conductor V2 and the fourth via conductor V4 is smaller than the distance between the first via conductor V1 and the third via conductor V3, and the first line 10 and the second line 20 can have larger inductance components near the first electrode T1 and the second electrode T2. The large inductance components act to cancel the capacitance components of the first electrode T1 and the second electrode T2, so as to achieve excellent signal transmission characteristics from a low frequency to a high frequency.

The first line conductor L1 and the third line conductor L3 may be vertically spaced apart from the second line conductor L2 and the fourth line conductor L4 (FIGS. 6B and 6C). In this configuration, the first via conductor V1 and the third via conductor V3 are positioned from the second line conductor L2 and the fourth line conductor L4 to a layer above, and the second via conductor V2 and the fourth via conductor V4 are positioned from this layer to a layer below. Accordingly, parts having large inductance components (the second via conductor V2 and the fourth via conductor V4 having a small distance) are close to the first electrode T1 and the second electrode T2 to easily enable the action of canceling the capacitance components of the first electrode T1 and the second electrode T2. This can thus achieve more excellent signal transmission characteristics from a low frequency to a high frequency.

The first line conductor L1 and the third line conductor L3 may be positioned closer to the first surface S1 than a center in the thickness direction of the insulating substrate 2. The second line conductor L2 and the fourth line conductor L4 may be positioned closer to the second surface S2 than the center in the thickness direction of the insulating substrate 2. In this configuration, the first via conductor V1 and the third via conductor V3 having a large distance are positioned in a long range including a vertical center of the insulating substrate 2, whereas the second via conductor V2 and the fourth via conductor V4 having a small distance are positioned close to the first electrode T1 and the second electrode T2. Furthermore, the second via conductor V2 and the fourth via conductor V4 having a small distance are shorter in vertical length than the first via conductor V1 and the third via conductor V3 having a large distance. Accordingly, the large inductance components of the second via conductor V2 and the fourth via conductor V4 act to cancel the capacitance components of the first electrode T1 and the second electrode T2. Meanwhile, the configuration can lower inhibition of impedance matching by the inductance components at a part distant from the first electrode T1 and the second electrode T2. This can thus achieve more excellent signal transmission characteristics from a low frequency to a high frequency.

The plurality of ground film conductors 31 may include the first ground film conductor 31a including the first opening O1 (FIGS. 4A and 1B) and the second ground film conductor 31b including the second opening O2 (FIGS. 4B to 5A and 1B). The first via conductor V1 and the third via conductor V3 may be positioned in the first opening O1, and the third via conductor V3 and the fourth via conductor V4 may be positioned in the second opening O2. The first opening O1 may be smaller than the second opening O2. In this configuration, the second via conductor V2 and the fourth via conductor V4 having large inductance components are positioned in the large second opening O2 to allow the second via conductor V2 and the fourth via conductor V4 to be more spaced apart from ground potential. Accordingly, the second via conductor V2 and the fourth via conductor V4 having large inductance components have decreased capacitance components to enhance the action of canceling the capacitance components of the first electrode T1 and the second electrode T2. This can thus improve impedance matching to achieve more excellent signal transmission characteristics from a low frequency to a high frequency.

The first electrode T1, the second electrode T2, the plurality of first ground electrodes Tg1, and the plurality of second ground electrodes Tg2 may each be larger in area than the third electrode T3 and the fourth electrode T4. This configuration leads to an increase in the capacitance components near the first electrode T1 and the second electrode T2. However, the increased capacitance components can be cancelled by the inductance-increasing action of the first via conductor V1 and the third via conductor V3 aligned with a small distance. In embodiment 1, the wiring substrate 1 can thus allow an increase in the sizes of the first electrode T1, the second electrode T2, the plurality of first ground electrodes Tg1, and the plurality of second ground electrodes Tg2, without inhibiting the signal transmission characteristics, so as to achieve better facilitated implementation on the second surface S2.

In a plan perspective view, the first opening O1 includes a center (corresponding to a center part) P1 that may be positioned between a center (corresponding to a center part) P2 of the second opening O2 and the first and second parallel line conductors H1 and H2 (FIG. 2). This configuration allows the first via conductor V1 and the third via conductor V3 to be disposed close to the center of the first opening O1 and the second via conductor V2 and the fourth via conductor V4 to be disposed close to the center of the second opening O2. This can thus promote impedance matching in the first opening O1 and impedance matching in the second opening O2 to achieve more excellent signal transmission characteristics.

The second opening O2 provided in the ground film conductor 31 in the fourteenth layer y14 may also be called a third opening O3 (FIG. 5A). The n-th via conductor Vn connected to the first electrode T1 and the (n+1)-th via conductor Vn+1 connected to the second electrode T2 are at least partially positioned in the third opening O3. In embodiment 1, the third opening O3 is identical in size and position in a plan perspective view to the second opening O2 positioned in a layer above the fourteenth layer y14. However, the second opening O2 and the third opening O3 may be different in size and position in a plan perspective view. The third opening O3 may be larger than the first opening O1. The third opening O3 may be smaller or larger than, or equal in size, to the second opening O2.

The first via conductor V1 and the third via conductor V3 may be positioned at a center in a lateral direction (corresponding to an X direction according to the present disclosure) of the first opening O1. The n-th via conductor Vn and the (n+1)-th via conductor Vn+1 may be positioned at a center in a lateral direction of the third opening O3. In this configuration, ground conductors are positioned symmetrically with respect to a conductor for signal transmission in the first opening O1 and the third opening O3, so as to further promote impedance matching.

Among the via conductors on the first line 10 (the i-th via conductor Vi, the first via conductor V1, the second via conductor V2, and the n-th via conductor Vn), the via conductor closest to the first electrode T1 is the n-th via conductor Vn, and the via conductor next closest is the second via conductor V2 (corresponding to an (n+2)-th via conductor according to the present disclosure). Similarly, among the via conductors on the second line 20 (the (i+1)-th via conductor Vi+1, the third via conductor V3, the fourth via conductor V4, and the (n+1)-th via conductor Vn+1), the via conductor closest to the second electrode T2 is the (n+1)-th via conductor Vn+1, and the via conductor next closest is the fourth via conductor V4 (corresponding to an (n+3)-th via conductor according to the present disclosure). The distance between the second via conductor V2 and the fourth via conductor V4, which are next closest to the first electrode T1 and the second electrode T2, may be smaller than the distance between the n-th via conductor Vn and the (n+1)-th via conductor Vn+1, which are closest to the first electrode T1 and the second electrode T2.

This configuration allows the second via conductor V2 and the fourth via conductor V4 having a small distance (corresponding to the (n+2)-th via conductor and the (n+3)-th via conductor according to the present disclosure) to be disposed close to the first electrode T1 and the second electrode T2. Accordingly, the large inductance components of the second via conductor V2 and the fourth via conductor V4 act to cancel the capacitance components of the first electrode T1 and the second electrode T2. Meanwhile, the configuration can lower an impedance-mismatching action at the part distant from the first electrode T1 and the second electrode T2. This can thus achieve more excellent signal transmission characteristics from a low frequency to a high frequency. Furthermore, along with the increases in the areas of the first electrode T1 and the second electrode T2, the n-th via conductor Vn can be brought close to the center of the first electrode T1 and the (n+1)-th via conductor Vn+1 can be brought close to the center of the second electrode T2. This achieves excellent signal transmission characteristics.

### Signal Transmission Characteristics

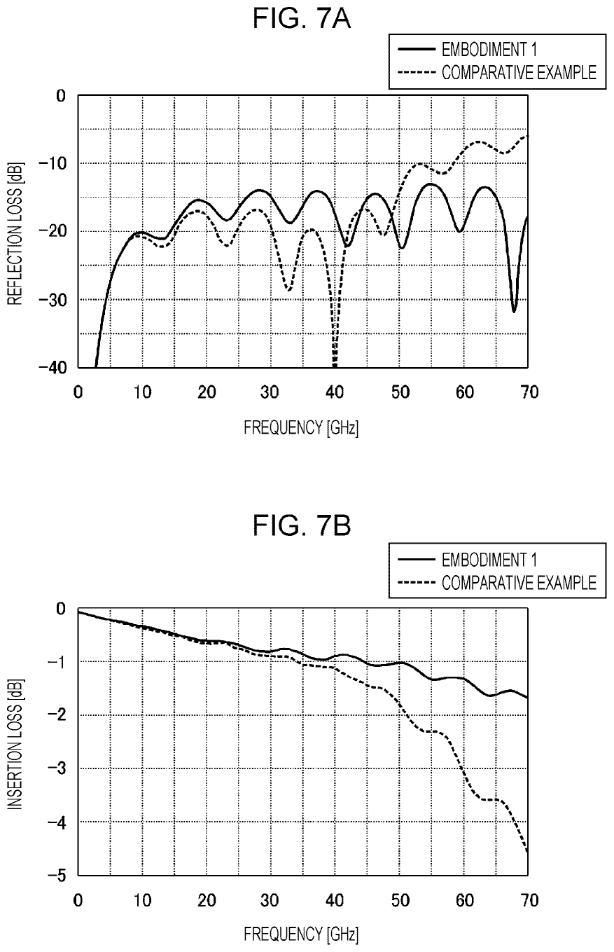

FIGS. 7A and 7B are graphs respectively indicating return losses and insertion losses of the wiring substrate 1 according to embodiment 1 and a wiring substrate according to a comparative example. The graphs in FIGS. 7A and 7B indicate simulation results of the wiring substrate 1 according to embodiment 1 and the wiring substrate according to the comparative example. In the comparative example, the wiring substrate is obtained by modifying constituent elements 1 to 4 as follows in the configuration according to embodiment 1. Constituent element 1: Removed are the second line conductor L2, the second via conductor V2, the n-th line conductor Ln, the n-th via conductor Vn, the fourth line conductor L4, the fourth via conductor V4, the (n+1)-th line conductor Ln+1, and the (n+1)-th via conductor Vn+1. Constituent element 2: In a plan perspective view, the first via conductor V1 according to embodiment 1 is positioned at the center of the first electrode T1, and the first via conductor V1 extends to the first electrode T1. Constituent element 3: In a plan perspective view, the second via conductor V2 is positioned at the center of the second electrode T2, and the second via conductor V2 extends to the second electrode T2. Constituent element 4: In a plan perspective view, the center of the first opening O1 and the center of the second opening O2 are overlapped with centers of the first via conductor V1 and the second via conductor V2.

The simulation results in FIGS. 7A and 7B indicate that, in comparison to the comparative example, embodiment 1 achieves excellent signal transmission characteristics from a low frequency to a high frequency. For example, in embodiment 1, the wiring substrate 1 has a low return loss also in a high frequency band, and a low insertion loss also in the high frequency band.

The wiring substrate 1 according to embodiment 1 has been described above with reference to the drawings. The wiring substrate 1 according to embodiment 1 is, however, not limited to the configuration as illustrated. For example, on the wiring substrate 1, the distance between the second via conductor V2 and the fourth via conductor V4 may be larger than, equal to, or smaller than, a distance between the first parallel line conductor H1 and the second parallel line conductor H2. Furthermore, the distance between the first via conductor V1 and the third via conductor V3 may be larger than, equal to, or smaller than, the distance between the n-th via conductor Vn and the (n+1)-th via conductor Vn+1. Embodiment 1 exemplifies the case where the second line conductor L2 and the fourth line conductor L4 are positioned in the twelfth layer y12 and the n-th line conductor Ln and the (n+1)-th line conductor Ln+1 are positioned in the fourteenth layer y14. Alternatively, the second line conductor L2 and the fourth line conductor L4 may be positioned in any one of the eighth layer y8 to the thirteenth layer y13, the n-th line conductor Ln and the (n+1)-th line conductor Ln+1 may be positioned in any one of the ninth layer y9 to the thirteenth layer y13, which is located below the layer including the second line conductor L2 and the fourth line conductor L4. Embodiment 1 exemplifies the case where the first line 10 and the second line 20 are plane symmetric with respect to a plane extending in an up and down direction as well as in the lateral direction between the first parallel line conductor H1 and the second parallel line conductor H2. Alternatively, the first line 10 and the second line 20 may each have a plane asymmetric portion. Embodiment 1 describes a strip line structure, but may alternatively adopt a so-called microstrip line structure in which the i-th line conductor Li and the first parallel line conductor H1 are connected from the third electrode T3 on the first surface S1 without providing the i-th via conductor Vi, and similarly, the (i+1)-th line conductor Li+1 and the second parallel line conductor H2 are connected from the fourth electrode T4 on the first surface S1 without providing the (i+1)-th via conductor Vi+1. The same applies to embodiment 2 to be described later.

### Embodiment 2

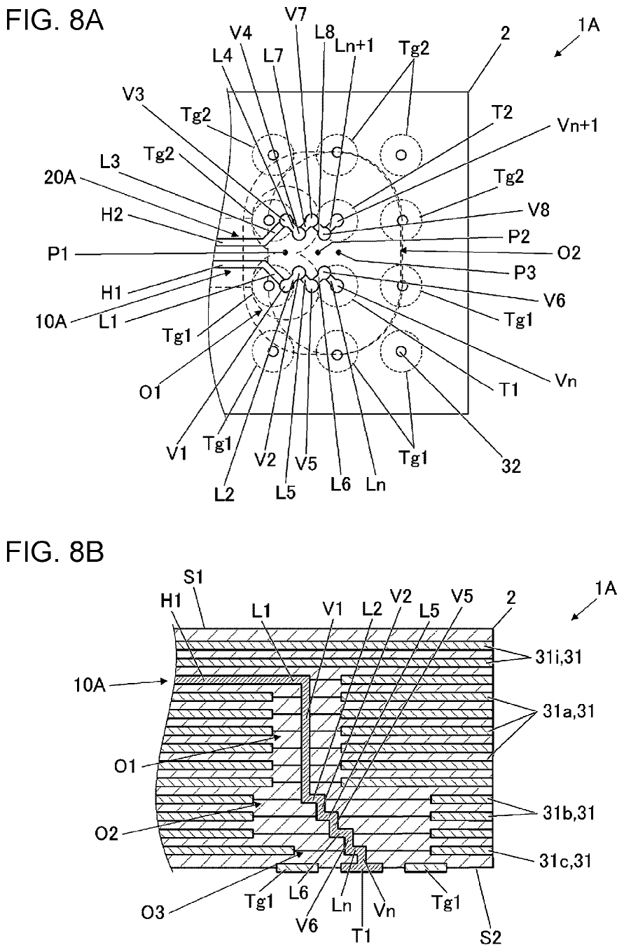

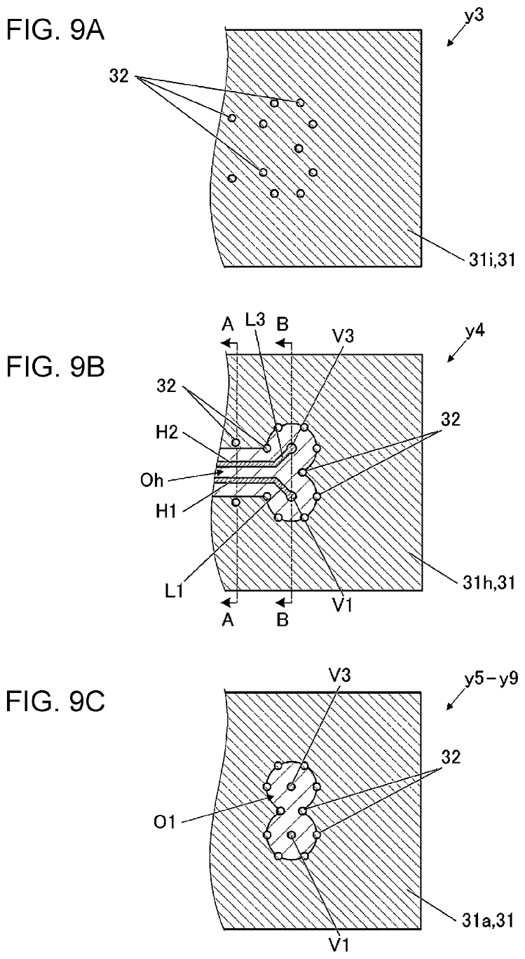

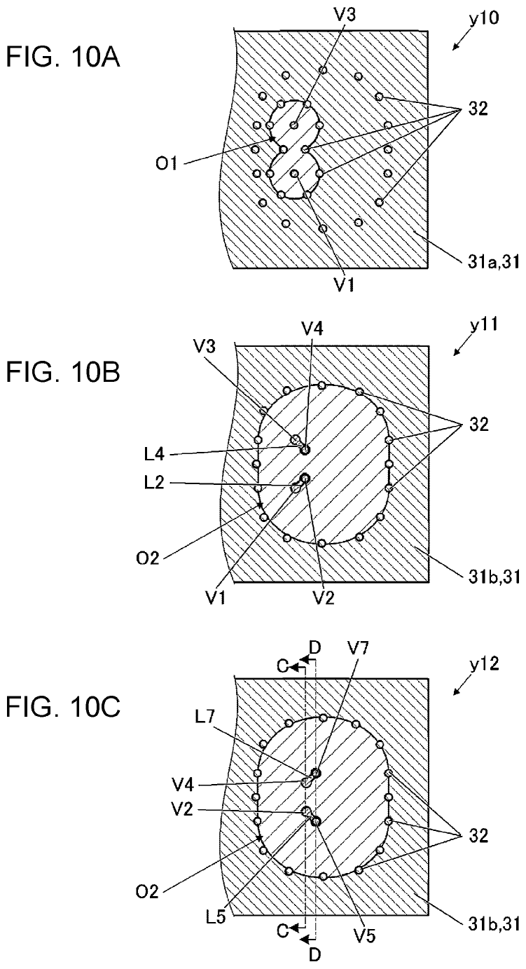

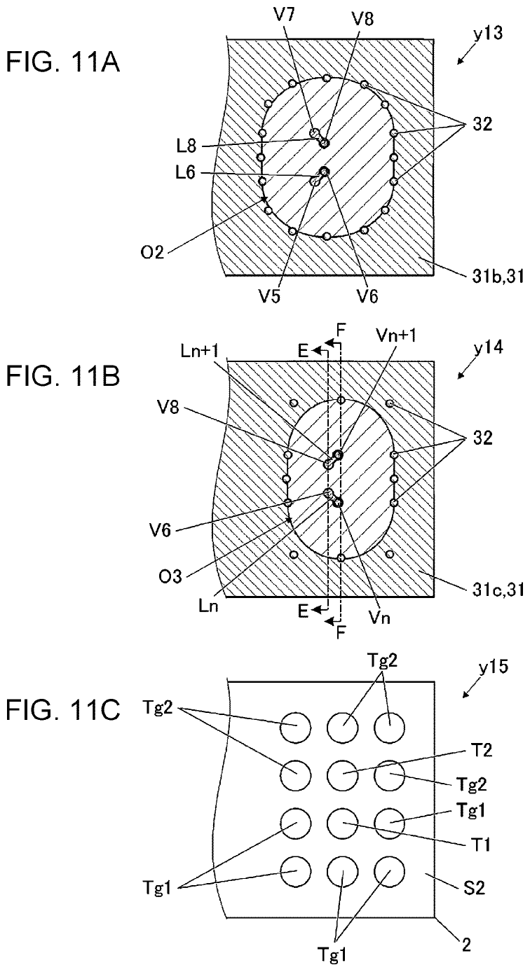

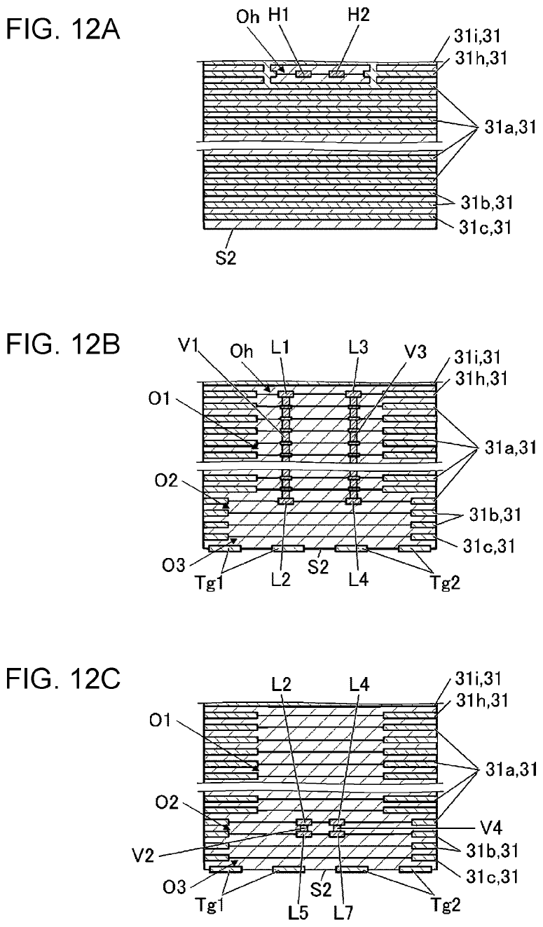

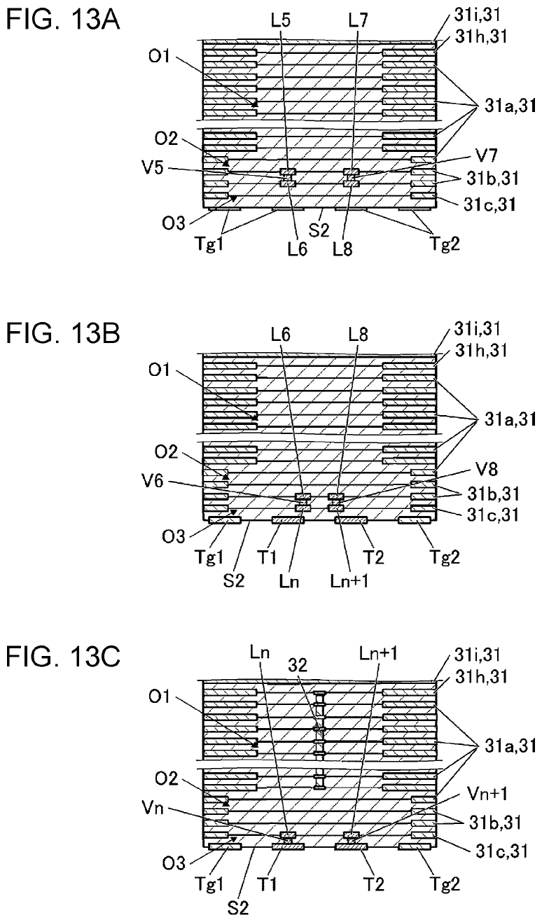

FIG. 8A is a plan perspective view of a principal part of a wiring substrate according to embodiment 2 of the present disclosure. FIG. 8B is a longitudinal sectional view of the principal part of the wiring substrate cut along a signal line in embodiment 2 of the present disclosure. FIGS. 9A to 9C are transverse sectional views respectively illustrating a third layer, a fourth layer, and fifth to ninth layers in the principal part in FIG. 8A. FIGS. 10A to 10C are transverse sectional views respectively illustrating a tenth layer, an eleventh layer, and a twelfth layer in the principal part in FIG. 8A. FIGS. 11A and 11B are transverse sectional views respectively illustrating a thirteenth layer and a fourteenth layer in the principal part in FIG. 8A. FIG. 11C is a view of a rear surface in the principal part in FIG. 8A. FIG. 11C perspectively illustrates the rear surface from above. FIG. 12A is a longitudinal sectional view taken along line A-A in FIG. 9B. FIG. 12B is a longitudinal sectional view taken along line B-B in FIG. 9B. FIG. 12C is a longitudinal sectional view taken along line C-C in FIG. 10C. FIG. 13A is a longitudinal sectional view taken along line D-D in FIG. 10C. FIG. 13B is a longitudinal sectional view taken along line E-E in FIG. 11B. FIG. 13C is a longitudinal sectional view taken along line F-F in FIG. 11B.

Embodiment 2 provides a wiring substrate 1A including an insulating substrate 2, a first line 10A and a second line 20A positioned adjacent to each other on the insulating substrate 2, and a plurality of ground film conductors 31 and a plurality of ground via conductors 32 positioned on the insulating substrate 2 and surrounding the first line 10A and the second line 20A.

The first line 10A includes a portion from a third electrode T3 to a second line conductor L2 and a portion from a first electrode T1 to an n-th line conductor Ln, which are configured similarly to corresponding portions of the first line 10 according to embodiment 1. The second line 20A includes a portion from a fourth electrode T4 to a fourth line conductor L4 and a portion from a second electrode T2 to an (n+1)-th line conductor Ln+1, which are configured similarly to corresponding portions of the second line 20 according to embodiment 1. Similar constituent elements will be denoted by the identical reference signs according to embodiment 1, and will not be repeatedly described in detail.

The first line 10A may include the second line conductor L2 and the n-th line conductor Ln that interpose the second via conductor V2, a fifth line conductor L5, a fifth via conductor V5, a sixth line conductor L6, and a sixth via conductor V6. The right part of the second line conductor L2 may be connected to the upper part of the second via conductor V2, the lower part of the second via conductor V2 may be connected to a left part of the fifth line conductor L5, and a right part of the fifth line conductor L5 may be connected to an upper part of the fifth via conductor V5. Furthermore, a lower part of the fifth via conductor V5 may be connected to a left part of the sixth line conductor L6, a right part of the sixth line conductor L6 may be connected to an upper part of the sixth via conductor V6, and a lower part of the sixth via conductor V6 may be connected to the left part of the n-th line conductor Ln. The right part, the left part, the upper part, and the lower part may alternatively be called a right end, a left end, an upper end, and a lower end, respectively.

The second line 20A may include the fourth line conductor L4 and the (n+1)-th line conductor Ln+1 that interpose the fourth via conductor V4, a seventh line conductor L7, a seventh via conductor V7, an eighth line conductor L8, and an eighth via conductor V8. The right part of the fourth line conductor L4 may be connected to the upper part of the fourth via conductor V4, the lower part of the fourth via conductor V4 may be connected to a left part of the seventh line conductor L7, and a right part of the seventh line conductor L7 may be connected to an upper part of the seventh via conductor V7. Furthermore, a lower part of the seventh via conductor V7 may be connected to a left part of the eighth line conductor L8, a right part of the eighth line conductor L8 may be connected to an upper part of the eighth via conductor V8, and a lower part of the eighth via conductor V8 may be connected to the left part of the (n+1)-th line conductor Ln+1. The right part, the left part, the upper part, and the lower part may alternatively be called a right end, a left end, an upper end, and a lower end, respectively.

The second line conductor L2 and the fourth line conductor L4 (FIG. 10B) may be positioned in the eleventh layer y11 and may have a distance gradually decreasing toward the right. The fifth line conductor L5 and the seventh line conductor L7 (FIG. 10C) may be positioned in the twelfth layer y12 and may have a distance gradually increasing toward the right. The sixth line conductor L6 and the eighth line conductor L8 (FIG. 11A) may be positioned in the thirteenth layer y13 and may have a distance gradually decreasing toward the right. In this configuration, the distance between the second via conductor V2 and the fourth via conductor V4 is smaller than the distance between the first via conductor V1 and the third via conductor V3, and the second via conductor V2 and the fourth via conductor V4 can have larger inductance components. Furthermore, the distance between the sixth via conductor V6 and the eighth via conductor V8 is smaller than the distance between the fifth via conductor V5 and the seventh via conductor V7, and the sixth via conductor V6 and the eighth via conductor V8 can have larger inductance components. The large inductance components thus act to cancel the capacitance components of the first electrode T1 and the second electrode T2, so as to achieve excellent signal transmission characteristics from a low frequency to a high frequency.

Furthermore, in the above configuration, the wiring substrate 1A includes a plurality of portions where via conductors can have a small distance (the distance between the second via conductor V2 and the fourth via conductor V4, and the distance between the sixth via conductor V6 and the eighth via conductor V8). The configuration thus enhances flexibility of impedance adjustment upon designing the wiring substrate 1A. This accordingly facilitates impedance matching to easily achieve excellent signal transmission characteristics.

The second line conductor L2 and the fourth line conductor L4 may include portions having the distance decreasing toward the second via conductor V2 and the fourth via conductor V4 in a planar view. That is, in a planar view, the second line conductor L2 may have an arc or circular arc shape projecting toward the fourth line conductor L4, an arc or circular arc shape depressed from the fourth line conductor L4, a zigzag shape bent at a right or certain angle at one or a plurality of points, a stepped shape, or a shape obtained by combining any of these shapes. Similarly, in a planar view, the fourth line conductor L4 may have an arc or circular arc shape projecting toward the second line conductor L2, an arc or circular arc shape depressed from the second line conductor L2, a zigzag shape bent at a right or certain angle at one or a plurality of points, a stepped shape, or a shape obtained by combining any of these shapes.

The fifth line conductor L5 and the seventh line conductor L7 may include portions having the distance increasing toward the fifth via conductor V5 and the seventh via conductor V7 in a planar view. That is, in a planar view, the fifth line conductor L5 may have an arc or circular arc shape projecting toward the seventh line conductor L7, an arc or circular arc shape depressed from the seventh line conductor L7, a zigzag shape bent at a right or certain angle at one or a plurality of points, a stepped shape, or a shape obtained by combining any of these shapes. Similarly, in a planar view, the seventh line conductor L7 may have an arc or circular arc shape projecting toward the fifth line conductor L5, an arc or circular arc shape depressed from the fifth line conductor L5, a zigzag shape bent at a right or certain angle at one or a plurality of points, a stepped shape, or a shape obtained by combining any of these shapes.

The sixth line conductor L6 and the eighth line conductor L8 may include portions having the distance decreasing toward the sixth via conductor V6 and the eighth via conductor V8 in a planar view. That is, in a planar view, the sixth line conductor L6 may have an arc or circular arc shape projecting toward the eighth line conductor L8, an arc or circular arc shape depressed from the eighth line conductor L8, a zigzag shape bent at a right or certain angle at one or a plurality of points, a stepped shape, or a shape obtained by combining any of these shapes. Similarly, in a planar view, the eighth line conductor L8 may have an arc or circular arc shape projecting toward the sixth line conductor L6, an arc or circular arc shape depressed from the sixth line conductor L6, a zigzag shape bent at a right or certain angle at one or a plurality of points, a stepped shape, or a shape obtained by combining any of these shapes.

Also in the above configuration, the distance between the second via conductor V2 and the fourth via conductor V4 is smaller than the distance between the first via conductor V1 and the third via conductor V3, and the second via conductor V2 and the fourth via conductor V4 can have larger inductance components. Furthermore, the distance between the sixth via conductor V6 and the eighth via conductor V8 is smaller than the distance between the fifth via conductor V5 and the seventh via conductor V7, and the sixth via conductor V6 and the eighth via conductor V8 can have larger inductance components. The large inductance components thus act to cancel the capacitance components of the first electrode T1 and the second electrode T2, so as to achieve excellent signal transmission characteristics from a low frequency to a high frequency. Furthermore, this enhances flexibility of impedance adjustment upon designing the wiring substrate 1A.

Among the via conductors on the first line 10A (the i-th via conductor Vi, the first via conductor V1, the second via conductor V2, the fifth via conductor V5, the sixth via conductor V6, and the n-th via conductor Vn), the via conductor closest to the first electrode T1 is the n-th via conductor Vn, and the via conductor next closest is the sixth via conductor V6 (corresponding to the (n+2)-th via conductor according to the present disclosure). Similarly, among the via conductors on the second line 20A (the (i+1)-th via conductor Vi+1, the third via conductor V3, the fourth via conductor V4, the seventh via conductor V7, the eighth via conductor V8, and the (n+1)-th via conductor Vn+1), the via conductor closest to the second electrode T2 is the (n+1)-th via conductor Vn+1, and the via conductor next closest is the eighth via conductor V8 (corresponding to the (n+3)-th via conductor according to the present disclosure). The distance between the sixth via conductor V6 and the eighth via conductor V8, which are next closest to the first electrode T1 and the second electrode T2 may be smaller than the distance between the n-th via conductor Vn and the (n+1)-th via conductor Vn+1, which are closest to the first electrode T1 and the second electrode T2.

This configuration allows the sixth via conductor V6 and the eighth via conductor V8 having a small distance (corresponding to the (n+2)-th via conductor and the (n+3)-th via conductor according to the present disclosure) to be disposed close to the first electrode T1 and the second electrode T2. Accordingly, the large inductance components of the sixth via conductor V6 and the eighth via conductor V8 act to cancel the capacitance components of the first electrode T1 and the second electrode T2. Meanwhile, the configuration can lower inhibition of impedance matching at a part distant from the first electrode T1 and the second electrode T2 by the large inductance components of the sixth via conductor V6 and the eighth via conductor V8. This can thus achieve more excellent signal transmission characteristics from a low frequency to a high frequency.

As in embodiment 1, the plurality of ground film conductors 31 is positioned in the second layer y2 to the fourteenth layer y14 of the insulating substrate 2. Furthermore, the openings Oi and Oh included in the plurality of ground film conductors 31 are configured similarly to the openings Oi and Oh according to embodiment 1. Moreover, in embodiment 2, the plurality of ground film conductors 31 may include the first ground film conductor 31a including the first opening O1 (FIGS. 8B, 9C, and 10A), the second ground film conductor 31b including the second opening O2 (FIGS. 8B and 10B to 11A), and a third ground film conductor 31c including the third opening O3 (FIGS. 8B and 11B).

The first opening O1 may be positioned in a layer (the fifth layer y5 to the tenth layer y10) penetrated by or including the first via conductor V1 and the third via conductor V3. The second opening O2 may be positioned in a layer (the eleventh layer y11 to the thirteenth layer y13) penetrated by or including the second via conductor V2 and the fourth via conductor V4, the fifth via conductor V5 and the seventh via conductor V7, or the sixth via conductor V6 and the eighth via conductor V8. The third opening O3 may be positioned in a layer (the fourteenth layer y14) above and next to the layer including the electrodes (T1, T2, Tg1, and Tg2).

The first opening O1 may be sized to promote impedance matching in the first via conductor V1 and the third via conductor V3.

The third opening O3 may be sized correspondingly to disposition of the plurality of first ground electrodes Tg1 and the plurality of second ground electrodes Tg2 so as to allow connections of the plurality of first ground electrodes Tg1 and the plurality of second ground electrodes Tg2 to the third ground film conductor 31c via the plurality of ground via conductors 32.

The second opening O2 may be larger than the first opening O1. The second opening O2 may be larger than, equal in size to, or smaller than, the third opening O3.

The second opening O2 is larger than the first opening Ol to allow the second via conductor V2, the fourth via conductor V4, the sixth via conductor V6, and the eighth via conductor V8 having large inductance components to be further spaced apart from the ground potential. Accordingly, the second via conductor V2, the fourth via conductor V4, the sixth via conductor V6, and the eighth via conductor V8 have smaller capacitance components to enhance the action of canceling the capacitance components of the first electrode T1 and the second electrode T2.

In a plan perspective view (FIG. 8A), the first opening O1 includes the center (corresponding to a center part) P1 that may be positioned between the center (corresponding to a center part) P2 of the second opening O2 and the first and second parallel line conductors H1 and H2. This configuration allows the first via conductor V1 and the third via conductor V3 to be disposed close to the center of the first opening O1 and the second via conductor V2 and the fourth via conductor V4 to be disposed close to the center of the second opening O2. This can thus promote impedance matching in the first opening O1 and impedance matching in the second opening O2 to achieve more excellent signal transmission characteristics.

In a plan perspective view (FIG. 8A), the center P2 of the second opening O2 may be positioned between a center P3 of the third opening O3 and the center P1 of the first opening O1. This configuration allows the second via conductor V2 and the fourth via conductor V4 to the eighth via conductor V8 to be disposed close to the center of the second opening O2 and the n-th via conductor Vn and the (n+1)-th via conductor Vn+1 to be disposed close to the center of the third opening O3. This can thus promote impedance matching in the second opening O2 and impedance matching in the third opening O3 to achieve more excellent signal transmission characteristics.

The first via conductor V1 and the third via conductor V3 may be positioned at the center in the lateral direction (corresponding to the X direction according to the present disclosure) of the first opening O1. The n-th via conductor Vn and the (n+1)-th via conductor Vn+1 may be positioned at the center in the lateral direction of the third opening O3. In this configuration, ground conductors are positioned symmetrically with respect to a conductor for signal transmission in the first opening O1 and the third opening O3, so as to further promote impedance matching.

The wiring substrate 1A according to embodiment 2 has been described above with reference to the drawings. The wiring substrate 1A according to embodiment 2 is, however, not limited to the configuration as illustrated. For example, on the wiring substrate 1A, the distance between the first parallel line conductor H1 and the second parallel line conductor H2, the distance between the second via conductor V2 and the fourth via conductor V4, and the distance between the sixth via conductor V6 and the eighth via conductor V8 may be all equal, all different, or partially equal with the remaining being different. The three distances may have any order in size. On the wiring substrate 1A, the distance between the first via conductor V1 and the third via conductor V3, the distance between the fifth via conductor V5 and the seventh via conductor V7, and the distance between the n-th via conductor Vn and the (n+1)-th via conductor Vn+1 may be all equal, all different, or partially equal with the remaining being different. The three distances may have any order in size.

### Embodiment 3

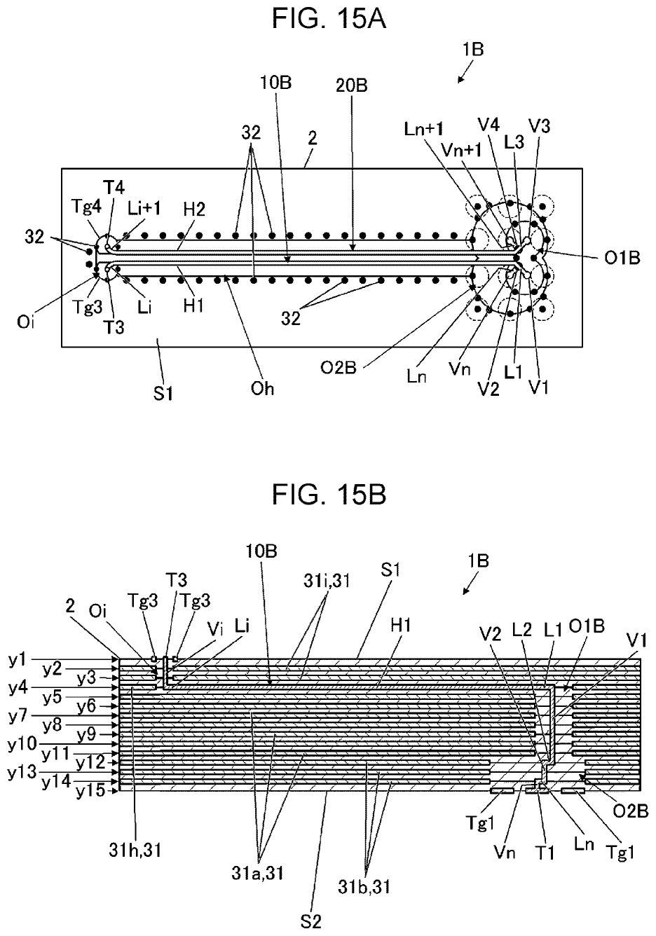

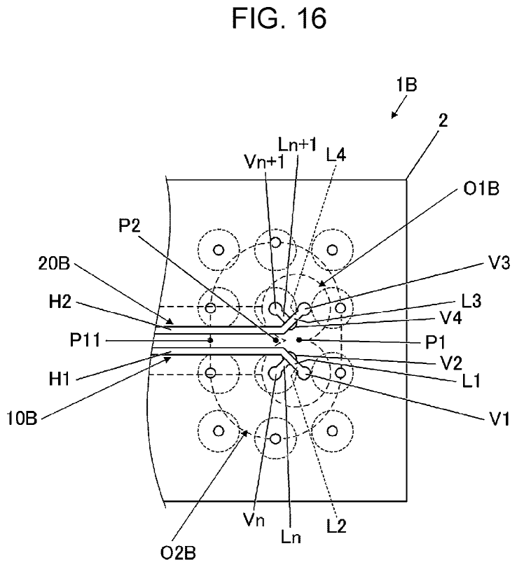

FIG. 15A is a plan perspective view of a wiring substrate according to embodiment 3 of the present disclosure. FIG. 15B is a longitudinal sectional view of the wiring substrate cut along a signal line in embodiment 3. FIG. 16 is a plan perspective view from above of a principal part of the wiring substrate according to embodiment 3.

Embodiment 3 exemplifies a wiring substrate 1B including a first opening O1B including a center (corresponding to a center part) P1 positioned on the right of a center (corresponding to a center part) P2 of a second opening O2B in a planar view. In embodiment 3, the wiring substrate 1B is principally different from the wiring substrate according to embodiment 1 or 2 in relative disposition between the first opening O1B and the second opening O2B, routing of a first line 10B, and routing of a second line 20B. The remaining elements may be similar to those according to embodiment 1 or 2.

As described above, the center P1 of the first opening O1B may be positioned on the right of the center P2 of the second opening O2B in a planar view. In other words, the center P2 of the second opening O2B may be positioned between the center P1 of the first opening O1B and a point P11 adjacent to parallel lines in a planar view. The point P11 adjacent to the parallel lines corresponds to a center P11 between a crossing point of an edge of the second opening O2B and the first parallel line conductor H1 and a crossing point of the edge of the second opening O2B and the second parallel line conductor H2. The first parallel line conductor H1 and the second parallel line conductor H2 may be parallel with each other. The first parallel line conductor H1 and the second parallel line conductor H2 may be straight or partially bent. The above disposition can also achieve excellent signal transmission characteristics from a low frequency to a high frequency.

In order to enable disposition of the first opening O1B as described above, the first via conductor V1 and the third via conductor V3 are positioned on the right of the second via conductor V2 and the fourth via conductor V4 in a planar view. As in embodiments 1 and 2, the distance between the first via conductor V1 and the third via conductor V3 is larger than the distance between the second via conductor V2 and the fourth via conductor V4. Furthermore, the n-th via conductor Vn and the (n+1)-th via conductor Vn+1 are positioned on the left of the second via conductor V2 and the fourth via conductor V4 in a planar view. The distance between the n-th via conductor Vn and the (n+1)-th via conductor Vn+1 is larger than the distance between the second via conductor V2 and the fourth via conductor V4.

The second line conductor L2 and the fourth line conductor L4 extend between a lower end of the first via conductor V1 and an upper end of the second via conductor V2, and between a lower end of the third via conductor V3 and an upper end of the fourth via conductor V4, respectively. That is, the second line conductor L2 and the fourth line conductor L4 extend leftward with a gradually decreasing distance. Furthermore, the n-th line conductor Ln and the (n+1)-th line conductor Ln+1 extend between the lower end of the third via conductor V3 and an upper end of the n-th via conductor Vn, and between a lower end of the fourth via conductor V4 and an upper end of the (n+1)-th via conductor Vn+1, respectively. That is, the n-th line conductor Ln and the (n+1)-th line conductor Ln+1 extend leftward with a gradually increasing distance.

In a planar view, the first line conductor L1 may be overlapped with part or entirety of the second line conductor L2, and the third line conductor L3 may be overlapped with part or entirety of the fourth line conductor L4.

Also in embodiment 3, the wiring substrate 1B can achieve excellent signal transmission characteristics from a low frequency to a high frequency.

Embodiment 3 exemplifies the case where, in the first opening O1B and the second opening O2B, the first line 10B and the second line 20B each include two stepped parts (see FIG. 15B) connecting a via conductor, a line conductor, and a via conductor. Alternatively, the first line 10B and the second line 20B may each include four or more stepped parts. Also in this configuration, the first via conductor V1 and the third via conductor V3 may be positioned on the right of the n-th via conductor Vn and the (n+1)-th via conductor Vn+1 in a planar view. This configuration can also achieve excellent signal transmission characteristics from a low frequency to a high frequency.

### Embodiment 4

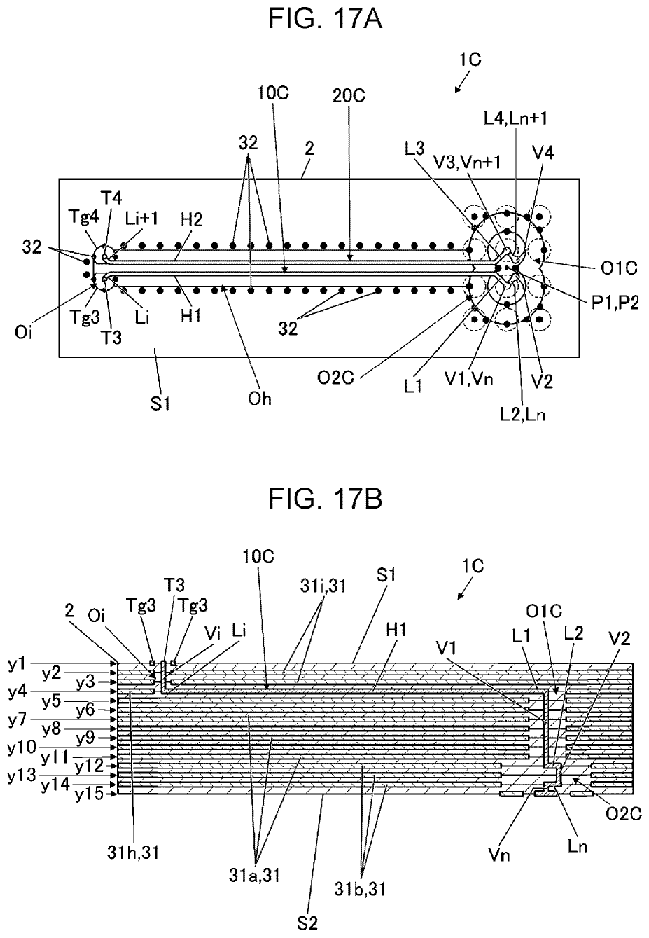

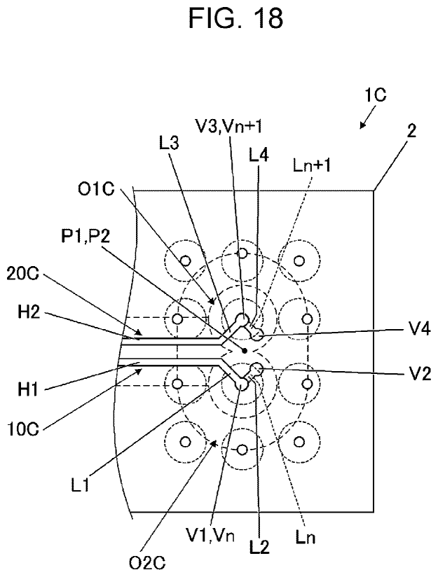

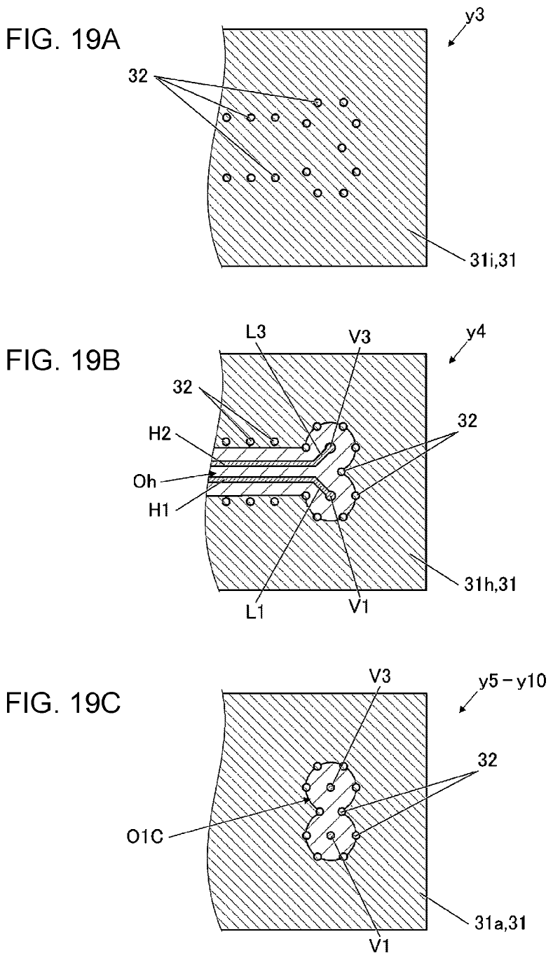

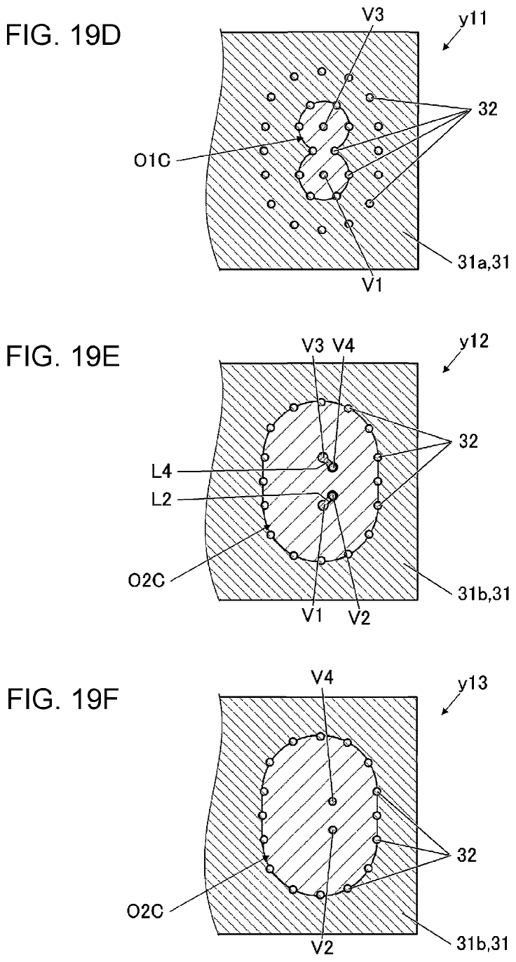

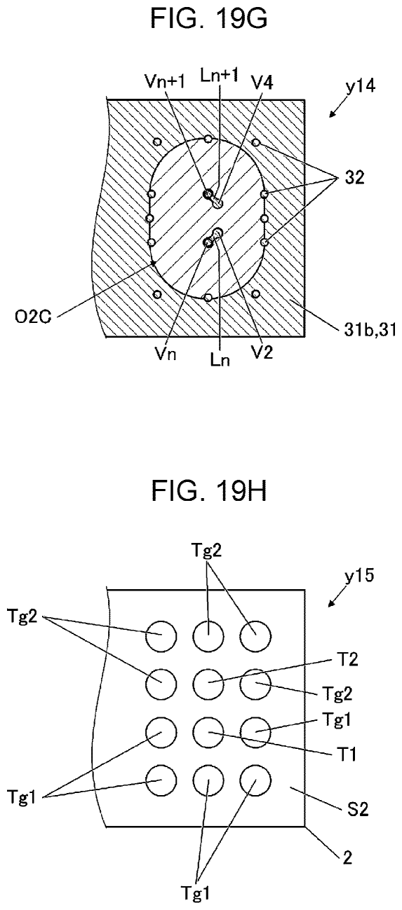

FIG. 17A is a plan perspective view of a wiring substrate according to embodiment 4 of the present disclosure. FIG. 17B is a longitudinal sectional view of the wiring substrate cut along a signal line in embodiment 4. FIG. 18 is a plan perspective view from above of a principal part of the wiring substrate according to embodiment 4. FIGS. 19A to 19H respectively illustrate a third layer, a fourth layer, fifth to tenth layers, an eleventh layer, a twelfth layer, a thirteenth layer, a fourteenth layer, and a rear surface in the principal part in FIG. 18.

Embodiment 4 exemplifies a wiring substrate 1C including a first opening O1C including a center (corresponding to a center part) P1 matching a center (corresponding to a center part) P2 of a second opening O2C in a planar view. Matching is not limited to strict matching and may include a case where a positional difference is equal to or less than a minimum value of a diameter of a via conductor. Embodiment 4 is principally different from embodiment 1, 2, or 3 in relative disposition between the first opening O1C and the second opening O2C, routing of a first line 10C, and routing of a second line 20C. The remaining elements may be similar to those according to embodiment 1, 2, or 3.

As described above, the center P1 of the first opening O1C may match the center P2 of the second opening O2C in a planar view. This disposition can also achieve excellent signal transmission characteristics from a low frequency to a high frequency.

In order to enable disposition of the first opening O1C as described above, the second via conductor V2 and the fourth via conductor V4 are laterally displaced from the first via conductor V1 and the third via conductor V3 in a planar view. As in embodiments 1 and 2, the distance between the first via conductor V1 and the third via conductor V3 is larger than the distance between the second via conductor V2 and the fourth via conductor V4. Furthermore, in a planar view, the n-th via conductor Vn and the (n+1)-th via conductor Vn+1 are laterally displaced from the second via conductor V2 and the fourth via conductor V4, and are positioned to be overlapped with the first via conductor V1 and the third via conductor V3, respectively. The distance between the n-th via conductor Vn and the (n+1)-th via conductor Vn+1 is larger than the distance between the second via conductor V2 and the fourth via conductor V4.

The second line conductor L2 and the fourth line conductor L4 extend between the lower end of the first via conductor V1 and the upper end of the second via conductor V2, and between the lower end of the third via conductor V3 and the upper end of the fourth via conductor V4, respectively. That is, the second line conductor L2 and the fourth line conductor L4 extend toward the second via conductor V2 and the fourth via conductor V4 with a gradually decreasing distance. Furthermore, the n-th line conductor Ln and the (n+1)-th line conductor Ln+1 extend between a lower end of the second via conductor V2 and the upper end of the n-th via conductor Vn, and between the lower end of the fourth via conductor V4 and the upper end of the (n+1)-th via conductor Vn+1, respectively. That is, the n-th line conductor Ln and the (n+1)-th line conductor Ln+1 extend toward the n-th via conductor Vn and the (n+1)-th via conductor Vn+1 with a gradually increasing distance.

In a planar view, the second line conductor L2 may be overlapped with part or entirety of the n-th line conductor Ln, and the fourth line conductor L4 may be overlapped with part or entirety of the (n+1)-th line conductor Ln+1.

Also in embodiment 4, the wiring substrate 1C can achieve excellent signal transmission characteristics from a low frequency to a high frequency.

Embodiment 4 exemplifies the case where, in the first opening O1C and the second opening O2C, the first line 10C and the second line 20C each include two stepped parts (see FIG. 17B) connecting a via conductor, a line conductor, and a via conductor. Alternatively, the first line 10C and the second line 20C may each include four or more stepped parts, and the n-th via conductor Vn and the (n+1)-th via conductor Vn+1 may be overlapped with the first via conductor V1 and the second via conductor V2 in a planar view. This configuration can also achieve excellent signal transmission characteristics from a low frequency to a high frequency.

### Embodiment 5

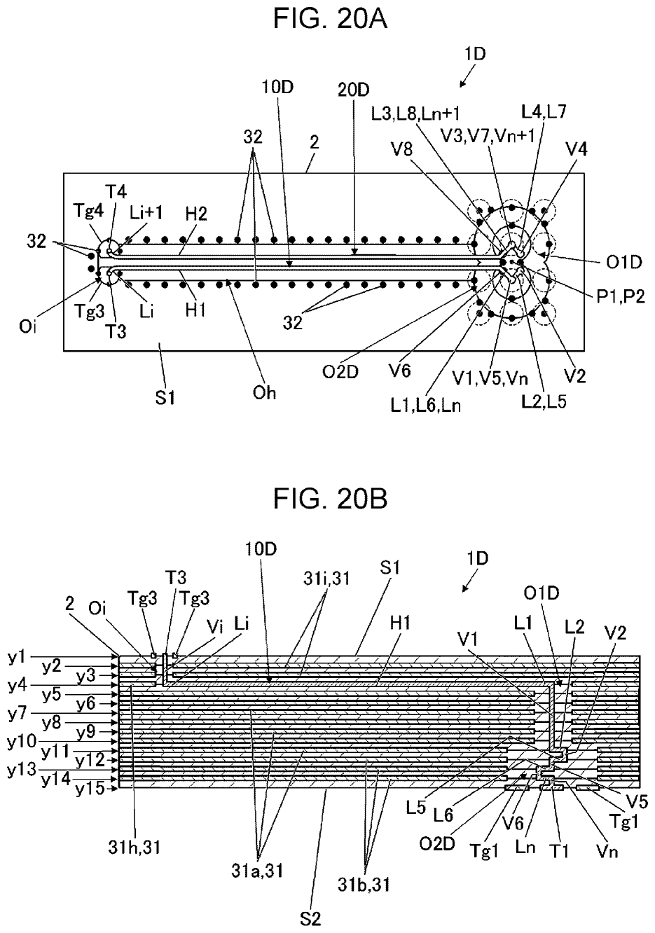

FIG. 20A is a plan perspective view of a wiring substrate according to embodiment 5 of the present disclosure. FIG. 20B is a longitudinal sectional view of the wiring substrate cut along a signal line in embodiment 5.

Similarly to embodiment 4, embodiment 5 exemplifies a wiring substrate 1D including a first opening O1D including a center (corresponding to a center part) P1 matching a center (corresponding to a center part) P2 of a second opening O2D in a planar view. Embodiment 5 further exemplifies the wiring substrate 1D including a first line 10D and a second line 20D each including four stepped parts (see FIG. 20B) connecting a via conductor, a line conductor, and a via conductor in the first opening O1D. Embodiment 5 is principally different from embodiment 1, 2, or 3 in relative disposition between the first opening O1D and the second opening O2D, routing of the first line 10D, and routing of the second line 20D. The remaining elements may be similar to those according to embodiment 1, 2, or 3.

As described above, the center P1 of the first opening O1D may match the center P2 of the second opening O2D in a planar view. This disposition can also achieve excellent signal transmission characteristics from a low frequency to a high frequency.

As in the wiring substrate 1D according to embodiment 5, the first via conductor V1, the fifth via conductor V5, and the n-th via conductor Vn may match in a planar view. Similarly, the third via conductor V3, the seventh via conductor V7, and the (n+1)-th via conductor Vn+1 may match in a planar view. Furthermore, the second via conductor V2 and the fourth via conductor V4 may be laterally displaced from the first via conductor V1 and the third via conductor V3 in a planar view. The distance between the second via conductor V2 and the fourth via conductor V4 may be smaller than the distance between the first via conductor V1 and the third via conductor V3.

Moreover, the sixth via conductor V6 and the eighth via conductor V8 may be displaced in a lateral direction from the first via conductor V1 and the third via conductor V3. The sixth via conductor V6 and the eighth via conductor V8 may be displaced opposite in the lateral direction from the second via conductor V2 and the fourth via conductor V4. The distance between the sixth via conductor V6 and the eighth via conductor V8 may be smaller than the distance between the first via conductor V1 and the third via conductor V3.

The second line conductor L2 and the fourth line conductor L4 extend between the lower end of the first via conductor V1 and the upper end of the second via conductor V2, and between the lower end of the third via conductor V3 and the upper end of the fourth via conductor V4, respectively. That is, the second line conductor L2 and the fourth line conductor L4 extend toward the second via conductor V2 and the fourth via conductor V4 with a gradually decreasing distance. Furthermore, the fifth line conductor L5 and the seventh line conductor L7 extend between the lower end of the second via conductor V2 and an upper end of the fifth via conductor V5, and between the lower end of the fourth via conductor V4 and an upper end of the seventh via conductor V7, respectively. That is, the fifth line conductor L5 and the seventh line conductor L7 extend toward the fifth via conductor V5 and the seventh via conductor V7 with a gradually increasing distance.

In a planar view, the second line conductor L2 may be overlapped with part or entirety of the fifth line conductor L5, and the fourth line conductor L4 may be overlapped with part or entirety of the seventh line conductor L7.

Furthermore, the sixth line conductor L6 and the eighth line conductor L8 extend between a lower end of the fifth via conductor V5 and an upper end of the sixth via conductor V6, and between a lower end of the seventh via conductor V7 and an upper end of the eighth via conductor V8, respectively. That is, the sixth line conductor L6 and the eighth line conductor L8 extend toward the sixth via conductor V6 and the eighth via conductor V8 with a gradually decreasing distance. Moreover, the n-th line conductor Ln and the (n+1)-th line conductor Ln+1 extend between a lower end of the sixth via conductor V6 and the upper end of the n-th via conductor Vn, and between a lower end of the eighth via conductor V8 and the upper end of the (n+1)-th via conductor Vn+1, respectively. That is, the n-th line conductor Ln and the (n+1)-th line conductor Ln+1 extend toward the n-th via conductor Vn and the (n+1)-th via conductor Vn+1 with a gradually increasing distance.

In a planar view, the sixth line conductor L6 may be overlapped with part or entirety of the n-th line conductor Ln, and the eighth line conductor L8 may be overlapped with part or entirety of the (n+1)-th line conductor Ln+1.

Also in embodiment 5, the wiring substrate 1D can achieve excellent signal transmission characteristics from a low frequency to a high frequency.

### Electronic Device and Electronic Module

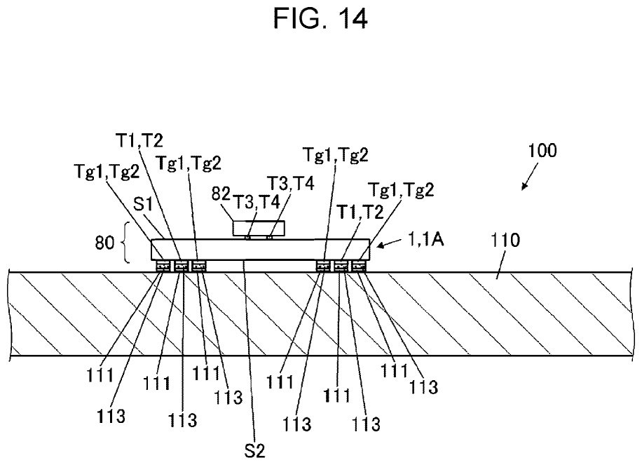

FIG. 14 is a view of an electronic device and an electronic module according to an embodiment of the present disclosure. The present embodiment provides an electronic device 80 including the wiring substrate 1 and an electron element 82 mounted on the wiring substrate 1. The wiring substrate 1 may be replaced with any one of the wiring substrates 1A to 1D. The electron element 82 is an element configured to receive or output high frequency signals, or to receive and output high frequency signals, and is electrically connected to the third electrode T3 and the fourth electrode T4 on the wiring substrate 1. The electron element 82 may be a semiconductor element. The high frequency signals may be differential signals.

The present embodiment provides an electronic module 100 including a module substrate 110, and the electronic device 80 mounted on the module substrate 110. The module substrate 110 may be equipped with any other electronic device, electron element, electrical element, or the like in addition to the electronic device 80. The module substrate 110 may include a plurality of electrodes 111 in a mount part of the electronic device 80, and the plurality of electrodes 111 may be respectively connected, via a conductive binder 113, to the first electrode T1, the second electrode T2, the first ground electrode Tg1, and the second ground electrode Tg2 on the wiring substrate 1.

In the present embodiment, the electronic device 80 and the electronic module 100 each include the wiring substrate 1 (or any one of the wiring substrates 1A to 1D) promoted to have broadband so as to achieve excellent characteristics from a low frequency to a high frequency.

### Industrial Applicability

The present disclosure is applicable to a wiring substrate, an electronic device, and an electronic module.

### REFERENCE SIGNS

1, 1A to 1D wiring substrate
2 insulating substrate
S1 first surface
S2 second surface
T1 first electrode
T2 second electrode
T3 third electrode
T4 fourth electrode
Tg1 first ground electrode
Tg2 second ground electrode
Tg3 third ground electrode
Tg4 fourth ground electrode
10, 10A first line
Vi i-th via conductor
Li i-th line conductor
H1 first parallel line conductor
L1 first line conductor
V1 first via conductor
L2 second line conductor
V2 second via conductor
L5 fifth line conductor
V5 fifth via conductor
L6 sixth line conductor
V6 sixth via conductor
Ln n-th line conductor
Vn n-th via conductor
20, 20A second line
Vi+1 (i+1)-th via conductor
Li+1 (i+1)-th line conductor
H2 second parallel line conductor
L3 third line conductor
V3 third via conductor
L4 fourth line conductor
V4 fourth via conductor
L7 seventh line conductor
V7 seventh via conductor
L8 eighth line conductor
V8 eighth via conductor
Ln+1 (n+1)-th line conductor
Vn+1 (n+1)-th via conductor
31, 31h, 31i ground film conductor
31a first ground film conductor
31b second ground film conductor
31c third ground film conductor
32 ground via conductor
O1, O1B to O1D first opening
O2, O2B to O2D second opening
O3 third opening
P1, P2, P3 center (center part)
80 electronic device
82 electron element
100 electronic module
110 module substrate

1. A wiring substrate comprising:
an insulating substrate;
a first line and a second line positioned adjacent to each other on the insulating substrate; and
a ground film conductor and a ground via conductor positioned on the insulating substrate and surrounding the first line and the second line; wherein
the first line includes
a first line conductor, a first via conductor connected to the first line conductor, a second line conductor connected to the first via conductor and extending opposite from the first line conductor with the first via conductor being interposed therebetween in a plan perspective view, and a second via conductor connected to the second line conductor and extending to a layer different from a layer including the first via conductor,
the second line includes
a third line conductor, a third via conductor connected to the third line conductor, a fourth line conductor connected to the third via conductor and extending opposite from the third line conductor with the third via conductor being interposed therebetween in a plan perspective view, and a fourth via conductor connected to the fourth line conductor and extending to a layer different from a layer including the third via conductor,
in a plan perspective view, the first line conductor and the third line conductor include portions having a distance increasing toward the first via conductor and the third via conductor, and the second line conductor and the fourth line conductor include portions having a distance decreasing toward the second via conductor and the fourth via conductor.

2. The wiring substrate according to claim 1, wherein
the first line conductor and the second line conductor are spaced apart from each other in a thickness direction of the insulating substrate, and
the third line conductor and the fourth line conductor are spaced apart from each other in the thickness direction of the insulating substrate.

3. The wiring substrate according to claim 2, wherein
the insulating substrate includes a first surface and a second surface positioned opposite to the first surface,
the first line conductor and the third line conductor are positioned closer to the first surface than the second surface, and
the second line conductor and the fourth line conductor are positioned closer to the second surface than the first surface.

4. The wiring substrate according to claim 1, wherein
the ground film conductor includes
a first ground film conductor including a first opening, and
a second ground film conductor including a second opening,
the first via conductor and the third via conductor are at least partially positioned in the first opening,
the second via conductor and the fourth via conductor are at least partially positioned in the second opening, and
the first opening is smaller than the second opening.

5. The wiring substrate according to claim 1, wherein
the first line further includes a fifth line conductor connected to the second via conductor and extending opposite from the second line conductor with the second via conductor being interposed therebetween in a plan perspective view, a fifth via conductor connected to the fifth line conductor and extending to a layer different from a layer including the second via conductor, a sixth line conductor connected to the fifth via conductor and extending opposite from the fifth line conductor with the fifth via conductor being interposed therebetween in a plan perspective view, and a sixth via conductor connected to the sixth line conductor and extending to a layer different from a layer including the fifth via conductor,
the second line further includes a seventh line conductor connected to the fourth via conductor and extending opposite from the third line conductor with the fourth via conductor being interposed therebetween in a plan perspective view, a seventh via conductor connected to the seventh line conductor and extending to a layer different from a layer including the fourth via conductor, an eighth line conductor connected to the seventh via conductor and extending opposite from the seventh line conductor with the seventh via conductor being interposed therebetween in a plan perspective view, and an eighth via conductor connected to the eighth line conductor and extending to a layer different from a layer including the seventh via conductor,
in a plan perspective view, the fifth line conductor and the seventh line conductor include portions having a distance increasing toward the fifth via conductor and the seventh via conductor, and the sixth line conductor and the eighth line conductor include portions having a distance decreasing toward the sixth via conductor and the eighth via conductor.

6. The wiring substrate according to claim 4, wherein
the first line conductor further includes a first parallel line conductor connected to the first line conductor on an opposite side of the first via conductor,
the second line conductor further includes a second parallel line conductor connected to the third line conductor on an opposite side of the third via conductor,
the first parallel line conductor and the second parallel line conductor are parallel with each other, and
in a plan perspective view, the first opening includes a center part positioned between the first and second parallel line conductors and a center part of the second opening.

7. The wiring substrate according to claim 4, wherein
in a plan perspective view, the first opening includes a center part matching a center part of the second opening.

8. The wiring substrate according to claim 4, wherein
the insulating substrate includes a first surface and a second surface positioned opposite to the first surface,
the first line further includes a first electrode positioned on the second surface, and an n-th via conductor connected to the first electrode,
the second line further includes a second electrode positioned on the second surface, and an (n+1)-th via conductor connected to the second electrode,
the ground film conductor includes a third ground film conductor including a third opening,
in a perspective view in an aligning direction of the first electrode and the second electrode, the first via conductor and the third via conductor are positioned at a center of the first opening, and the n-th via conductor and the (n+1)-th via conductor are positioned at a center of the third opening.

9. The wiring substrate according to claim 8, wherein
the first line includes an n-th line conductor connected to the n-th via conductor on an opposite side of the first electrode, and an (n+2)-th via conductor connected to the n-th line conductor and extending to a layer different from a layer including the n-th via conductor,
the second line includes an (n+1)-th line conductor connected to the (n+1)-th via conductor on an opposite side of the second electrode, and an (n+3)-th via conductor connected to the (n+1)-th line conductor and extending to a layer different from a layer including the (n+1)-th via conductor, and
the (n+2)-th via conductor and the (n+3)-th via conductor have a distance smaller than a distance between the n-th via conductor and the (n+1)-th via conductor.

10. An electronic device comprising:
the wiring substrate according to claim 1; and
an electron element mounted on the wiring substrate.

11. An electronic module comprising:
the electronic device according to claim 10; and
a module substrate equipped with the electronic device.

12. The wiring substrate according to claim 2, wherein
the ground film conductor includes
a first ground film conductor including a first opening, and
a second ground film conductor including a second opening,
the first via conductor and the third via conductor are at least partially positioned in the first opening,
the second via conductor and the fourth via conductor are at least partially positioned in the second opening, and
the first opening is smaller than the second opening.

13. The wiring substrate according to claim 3, wherein
the ground film conductor includes
a first ground film conductor including a first opening, and
a second ground film conductor including a second opening,
the first via conductor and the third via conductor are at least partially positioned in the first opening,
the second via conductor and the fourth via conductor are at least partially positioned in the second opening, and
the first opening is smaller than the second opening.

14. The wiring substrate according to claim 2, wherein
the first line further includes a fifth line conductor connected to the second via conductor and extending opposite from the second line conductor with the second via conductor being interposed therebetween in a plan perspective view, a fifth via conductor connected to the fifth line conductor and extending to a layer different from a layer including the second via conductor, a sixth line conductor connected to the fifth via conductor and extending opposite from the fifth line conductor with the fifth via conductor being interposed therebetween in a plan perspective view, and a sixth via conductor connected to the sixth line conductor and extending to a layer different from a layer including the fifth via conductor,
the second line further includes a seventh line conductor connected to the fourth via conductor and extending opposite from the third line conductor with the fourth via conductor being interposed therebetween in a plan perspective view, a seventh via conductor connected to the seventh line conductor and extending to a layer different from a layer including the fourth via conductor, an eighth line conductor connected to the seventh via conductor and extending opposite from the seventh line conductor with the seventh via conductor being interposed therebetween in a plan perspective view, and an eighth via conductor connected to the eighth line conductor and extending to a layer different from a layer including the seventh via conductor,
in a plan perspective view, the fifth line conductor and the seventh line conductor include portions having a distance increasing toward the fifth via conductor and the seventh via conductor, and the sixth line conductor and the eighth line conductor include portions having a distance decreasing toward the sixth via conductor and the eighth via conductor.

15. The wiring substrate according to claim 3, wherein
the first line further includes a fifth line conductor connected to the second via conductor and extending opposite from the second line conductor with the second via conductor being interposed therebetween in a plan perspective view, a fifth via conductor connected to the fifth line conductor and extending to a layer different from a layer including the second via conductor, a sixth line conductor connected to the fifth via conductor and extending opposite from the fifth line conductor with the fifth via conductor being interposed therebetween in a plan perspective view, and a sixth via conductor connected to the sixth line conductor and extending to a layer different from a layer including the fifth via conductor,
the second line further includes a seventh line conductor connected to the fourth via conductor and extending opposite from the third line conductor with the fourth via conductor being interposed therebetween in a plan perspective view, a seventh via conductor connected to the seventh line conductor and extending to a layer different from a layer including the fourth via conductor, an eighth line conductor connected to the seventh via conductor and extending opposite from the seventh line conductor with the seventh via conductor being interposed therebetween in a plan perspective view, and an eighth via conductor connected to the eighth line conductor and extending to a layer different from a layer including the seventh via conductor,
in a plan perspective view, the fifth line conductor and the seventh line conductor include portions having a distance increasing toward the fifth via conductor and the seventh via conductor, and the sixth line conductor and the eighth line conductor include portions having a distance decreasing toward the sixth via conductor and the eighth via conductor.

16. The wiring substrate according to claim 4, wherein
the first line further includes a fifth line conductor connected to the second via conductor and extending opposite from the second line conductor with the second via conductor being interposed therebetween in a plan perspective view, a fifth via conductor connected to the fifth line conductor and extending to a layer different from a layer including the second via conductor, a sixth line conductor connected to the fifth via conductor and extending opposite from the fifth line conductor with the fifth via conductor being interposed therebetween in a plan perspective view, and a sixth via conductor connected to the sixth line conductor and extending to a layer different from a layer including the fifth via conductor,
the second line further includes a seventh line conductor connected to the fourth via conductor and extending opposite from the third line conductor with the fourth via conductor being interposed therebetween in a plan perspective view, a seventh via conductor connected to the seventh line conductor and extending to a layer different from a layer including the fourth via conductor, an eighth line conductor connected to the seventh via conductor and extending opposite from the seventh line conductor with the seventh via conductor being interposed therebetween in a plan perspective view, and an eighth via conductor connected to the eighth line conductor and extending to a layer different from a layer including the seventh via conductor,
in a plan perspective view, the fifth line conductor and the seventh line conductor include portions having a distance increasing toward the fifth via conductor and the seventh via conductor, and the sixth line conductor and the eighth line conductor include portions having a distance decreasing toward the sixth via conductor and the eighth via conductor.

17. The wiring substrate according to claim 12, wherein
the first line further includes a fifth line conductor connected to the second via conductor and extending opposite from the second line conductor with the second via conductor being interposed therebetween in a plan perspective view, a fifth via conductor connected to the fifth line conductor and extending to a layer different from a layer including the second via conductor, a sixth line conductor connected to the fifth via conductor and extending opposite from the fifth line conductor with the fifth via conductor being interposed therebetween in a plan perspective view, and a sixth via conductor connected to the sixth line conductor and extending to a layer different from a layer including the fifth via conductor,
the second line further includes a seventh line conductor connected to the fourth via conductor and extending opposite from the third line conductor with the fourth via conductor being interposed therebetween in a plan perspective view, a seventh via conductor connected to the seventh line conductor and extending to a layer different from a layer including the fourth via conductor, an eighth line conductor connected to the seventh via conductor and extending opposite from the seventh line conductor with the seventh via conductor being interposed therebetween in a plan perspective view, and an eighth via conductor connected to the eighth line conductor and extending to a layer different from a layer including the seventh via conductor,
in a plan perspective view, the fifth line conductor and the seventh line conductor include portions having a distance increasing toward the fifth via conductor and the seventh via conductor, and the sixth line conductor and the eighth line conductor include portions having a distance decreasing toward the sixth via conductor and the eighth via conductor.

18. The wiring substrate according to claim 13, wherein
the first line further includes a fifth line conductor connected to the second via conductor and extending opposite from the second line conductor with the second via conductor being interposed therebetween in a plan perspective view, a fifth via conductor connected to the fifth line conductor and extending to a layer different from a layer including the second via conductor, a sixth line conductor connected to the fifth via conductor and extending opposite from the fifth line conductor with the fifth via conductor being interposed therebetween in a plan perspective view, and a sixth via conductor connected to the sixth line conductor and extending to a layer different from a layer including the fifth via conductor,
the second line further includes a seventh line conductor connected to the fourth via conductor and extending opposite from the third line conductor with the fourth via conductor being interposed therebetween in a plan perspective view, a seventh via conductor connected to the seventh line conductor and extending to a layer different from a layer including the fourth via conductor, an eighth line conductor connected to the seventh via conductor and extending opposite from the seventh line conductor with the seventh via conductor being interposed therebetween in a plan perspective view, and an eighth via conductor connected to the eighth line conductor and extending to a layer different from a layer including the seventh via conductor,
in a plan perspective view, the fifth line conductor and the seventh line conductor include portions having a distance increasing toward the fifth via conductor and the seventh via conductor, and the sixth line conductor and the eighth line conductor include portions having a distance decreasing toward the sixth via conductor and the eighth via conductor.

19. The wiring substrate according to claim 12, wherein
the first line conductor further includes a first parallel line conductor connected to the first line conductor on an opposite side of the first via conductor,
the second line conductor further includes a second parallel line conductor connected to the third line conductor on an opposite side of the third via conductor,
the first parallel line conductor and the second parallel line conductor are parallel with each other, and
in a plan perspective view, the first opening includes a center part positioned between the first and second parallel line conductors and a center part of the second opening.

20. The wiring substrate according to claim 13, wherein
the first line conductor further includes a first parallel line conductor connected to the first line conductor on an opposite side of the first via conductor,
the second line conductor further includes a second parallel line conductor connected to the third line conductor on an opposite side of the third via conductor,
the first parallel line conductor and the second parallel line conductor are parallel with each other, and
in a plan perspective view, the first opening includes a center part positioned between the first and second parallel line conductors and a center part of the second opening.
